(19) United States
(12) Patent Application Publication
(10) Pub. No.: US 2024/0385529 A1
(43) Pub. Date: Nov. 21, 2024

(54) Material for Enhancing the Effects of Exercise

(71) Applicant: Michael Rudan, Toronto (CA)

(72) Inventor: Michael Rudan, Toronto (CA)

(21) Appl. No.: 18/785,927

(22) Filed: Jul. 26, 2024

Related U.S. Application Data
(62) Division of application No. 16/319,168, filed on Jan. 18, 2019.
(60) Provisional application No. 62/365,662, filed on Jul. 22, 2016.
(60) Provisional application No. 62/371,204, filed on Aug. 4, 2016.
(60) Provisional application No. 62/449,520, filed on Jan. 23, 2017.
(60) Provisional application No. 62/516,937, filed on Jun. 8, 2017.

(51) Int. Cl. G03F 7/00; A41D 13/00; A41D 19/00; A41D 31/18; A43B 5/06; A43B 13/04; A43B 13/18; A43B 17/00; A43B 17/02; A63B 21/00; A63B 21/065; A63B 24/00; A63B 71/06; B32B 25/04

(52) U.S. Cl. CPC G03F 7/70466; A41D 13/0015; A41D 19/0027; A41D 19/0055; A41D 31/18; A43B 5/06; A43B 13/04; A43B 13/184; A43B 17/006; A43B 17/02; A63B 21/065; A63B 21/4043; A63B 24/0062; A63B 71/0619; B32B 25/042; A41D 2500/50; A41D 2600/10; A63B 2071/0655; A63B 2209/00; A63B 2220/56; A63B 2220/836; B32B 2437/02

(57) ABSTRACT

A compressible material is provided for use with athletic equipment and apparel for enhancing the effects of physical exercise for a person. The material can include one or more compression members that extend from shoes, insoles for shoes, exercise gloves, wraps for exercise equipment, exercise mat or floor covering, headbands, socks, exercise garments, free weights and sports helmets. The compression members can be made of one or more of rubber, thermoplastic rubber, foam rubber, polyurethane rubber, silicone rubber, thermoplastic resin and thermoplastic elastomer. Positioning the compressible material such that it is between the user and any surface for example when exercising, requires the person to maintain balance while performing the exercise by using other muscles that would not ordinarily be used during the exercise, and provides proprioceptive feedback to the person's central nervous system.

### PRIORITY STATEMENT & CROSS-REFERENCE TO RELATED APPLICATIONS

This application is a divisional of U.S. patent application Ser. No. 16/319,168 entitled “Material for Enhancing the Effects of Exercise” filed on Jan. 18, 2019 in the name of Michael Ruden; which is the National Stage of, and therefore, claims the benefit of International Application No. PCT/CA2017/050874 filed Jul. 20, 2017, now expired; which claims priority of U.S. Provisional Patent Application Ser. No. 62/365,662 filed Jul. 20, 2016; Ser. No. 62/371,204 filed Aug. 4, 2016; Ser. No. 62/449,520 filed Jan. 23, 2017; and Ser. No. 62/516,937 filed Jun. 8, 2017, which are all incorporated by reference into this application in their entirety.

### TECHNICAL FIELD OF THE INVENTION

The present disclosure is related to the field of materials for enhancing physical exercise, in particular, compressible materials that can be incorporated into athletic footwear, apparel and equipment and provide a proprioceptive effect on a person when worn during physical exercise.

### BACKGROUND OF THE INVENTION

It is often difficult for people who are not in the best of physical shape to improve their physical well-being and health. Also, those who were more physically active and fit when they were younger have a tendency to become more sedentary as they age, and their physical well-being and health can decline. In addition, those who have suffered a physical injury, notwithstanding that they may have been physically fit and healthy prior to the injury, may find it difficult to continue exercising as they could prior to their injury. In all of these cases, there is a need for improved physical fitness footwear, apparel and equipment that can enable anyone to enhance their exercise regime by causing them to use additional muscles to maintain their balance while exercise while lowering the amount of weight or force required so as to not overtax the person's joints and muscles and improve proprioception, especially if they had been previously sedentary or are recovering from an injury.

In The Role of Proprioception in the Management and Rehabilitation of Athletic Injuries (SM Lephart et al., The American Journal of Sports Medicine, Vol. 25, No. 1) proprioception is defined as a specialized sensory modality of touch and encompasses the sensations of joint movement and joint position. Proprioception contributes to motor programing for neuromuscular control required for precision movements and also contributes to muscle reflexes, providing dynamic joint stability. Proprioceptive receptors found in the skin, muscles and joints provide input to the central nervous system (“CNS”) and, along with visual and vestibular centres, contributes afferent information to the CNS regarding body position and balance. A sports injury or other musculoskeletal trauma can lead to proprioceptive defects. Proprioceptive rehabilitation seeks to retrain altered afferent pathways to enhance sensation of joint movement. There is a need for improved physical fitness footwear, apparel and equipment that can enable anyone to train or retrain afferent pathways to improve functional stability of the person's joints and body.

It is, therefore, desirable to provide compressible materials that can be incorporated into athletic footwear, apparel and equipment to enhance the effects of physical exercise.

### SUMMARY OF THE INVENTION

A compressible material for athletic footwear, apparel and equipment is provided to enhance the effects of physical exercise. In embodiments, compressible protrusions can be added to the anterior (palm) or dorsal (top) region as well as on the phalange region of gloves used for exercising, weight lifting or running, to the soles, toes or instep of shoes used for exercising, weight lifting or running, to the soles of galoshes that can be slipped onto regular shoes, to the soles of insoles for shoes, to the bottom of exercise mats, to the equipment side of barbell wraps, to the outside of joint wraps for use with elbows or knees, athletic apparel such as pants, tights, leggings, shirts, hoodies or one-piece exercise clothing, to footwear such as socks, shoes, or shoe covers, and to fitness or gym flooring. The addition of the compressible protrusions can operate similarly to exercise equipment that comprise compressible spheres or hemispheres, such as used in Pilates and in other forms of exercising. The compressible hemispheres can also cause the user to actively hold the muscles, joints and body in a proper alignment providing proprioceptive feedback to the CNS. These voluntary movements can be repeated and stored as central commands. This patterning of the brain allows various skills to be performed without continuous without continuous reference to consciousness and can increase the conscious and unconscious awareness of the joint or limb in motion.

The placement of compressible protrusions on the bottom of weight lifting shoes on a person lifting weights, as an example, requires the person hold the body in proper alignment, adding proprioceptive elements to the exercise to assist in proper patterning of the CNS and to exert additional effort and use other muscles, such as their core muscles, to maintain balance in addition to the weight lifting exercise they are carrying out, such as bicep curls, front and side dumbbell lateral raises and the like. In such shoes, the sole can have one or more different sized compressible hemispheres, such as larger diameter hemispheres under the ball or heel of the shoe, and smaller diameter hemispheres disposed between and around the larger hemispheres. In some embodiments, a running shoe can comprise one or more compressible hemispheres disposed on the sole, facing downwards. In some embodiments, compressible hemispheres can be placed on the bottom of galoshes, which can be slipped onto regular shoes. In other embodiments, an insole having compressible hemispheres on the bottom thereof, facing downwards, can be used in regular shoes to similar effect.

In some embodiments, exercise equipment can comprise such compressible hemispheres. In one example, bar wraps can have one or more such compressible hemispheres disposed on one side of the wrap, the side that faces outwardly towards the user such that the user contacts the compressible hemispheres directly when grabbing the bar. In other embodiments, a workout mat or floor covering can comprise one or more compressible hemispheres extending upwards from the floor when the mat or floor covering is laid out for use on the floor. In some embodiments, a joint wrap for elbows or knees can comprise one or more compressible hemispheres extending outwardly from the wrap. The joint wrap can be comprised of an elastic tube that can stretch and slip onto a person's arm or leg. The placement of the compressible hemispheres can enable the user to perform exercises where contact by the elbows or knees to a hard surface, such as a floor or wall, via the compressible hemispheres.

In some embodiments, athletic apparel such as pants, tights, leggings, shirts, hoodies or one-piece exercise clothing can comprise one or more compressible hemispheres extending outwardly from the apparel. The compressible hemispheres can be affixed to the apparel. In some embodiments the compressible hemispheres can be removably attached to the apparel. In some embodiments the apparel can comprise pockets for removably attaching the compressible hemispheres at the desired locations. In other embodiments the compressible hemispheres can be attached using Velcro™, hooks, buttons, snaps, straps or other suitable removable attachment as well known to those skilled in the art. The placement of the compressible hemispheres can enable the user to perform exercises where there can be contact by the elbows, knees or other body part to a hard surface, such as a floor or wall, via the compressible hemispheres.

In some embodiments, a sock, shoe cover, or other foot covering can comprise one or more compressible hemispheres disposed on the sole, the toe portion, the heal portion, the leg portion or elsewhere on the foot covering, protruding outward.

In some embodiments, compressible material can be positioned so as to be between the toes. The compressible material between the toes can activate the nerves in the toes and provide proprioceptive feedback to the CNS.

In some embodiments, the compressible hemispheres can be comprised of an elastomeric material, as well known to those skilled in the art. In some embodiments, the elastomeric material can comprise can comprise one or more of a group comprising of rubber, thermoplastic rubber, foam rubber, polyurethane rubber, silicone rubber, thermoplastic resin and thermoplastic elastomer. In further embodiments, the exterior of the compressible hemisphere can be composed of a durable material, such as plastic or synthetic fiber and the interior of the compressible protrusion can comprise one or more of a liquid, a gel and a gas, such as air or combinations thereof.

Broadly stated, in some embodiments, a sheet material can be provided for enhancing the effects of physical exercise for a person, the sheet material comprising: a sheet of planar material comprising a first elastomeric material; and at least one protrusion extending from a first side of the sheet of planar material, the at least one protrusion comprising one or both of the first elastomeric material and a second elastomeric material, wherein the sheet material is configured to be disposed between the person and a piece of exercise equipment or a hard surface.

Broadly stated, in some embodiments, a glove can be provided for enhancing the effects of physical exercise for a person, the glove comprising at least one compressible protrusion disposed on the glove extending outwardly from the glove.

Broadly stated, in some embodiments, the glove can comprise an anterior region and the at least one compressible protrusion can extend outwardly from the anterior region.

Broadly stated, in some embodiments, the glove can comprise a dorsal region and the at least one compressible protrusion can extend outwardly from the dorsal region.

Broadly stated, in some embodiments, the glove can comprise a plurality of phalange regions and the at least one compressible protrusion can extend outwardly from at least one of the plurality of phalanges regions.

Broadly stated, in some embodiments, each of the plurality of phalange regions can comprise a fingertip region and the at least one compressible protrusion can extend outwardly from at least one of the fingertip regions of the plurality of phalanges regions.

Broadly stated, in some embodiments, each of the plurality of phalange regions can comprise an anterior phalange region and the at least one compressible protrusion can comprise a first anterior compressible protrusion and a second anterior compressible protrusion each can extend outwardly from at least one of the anterior phalange regions of the plurality of phalanges regions.

Broadly stated, in some embodiments, the first anterior compressible protrusion and the second anterior compressible protrusion can be connected by an anterior connecting material.

Broadly stated, in some embodiments, each of the plurality of phalange regions can comprise an dorsal phalange region and the at least one compressible protrusion can comprise a first dorsal compressible protrusion and a second dorsal compressible protrusion each can extend outwardly from at least one of the dorsal phalange regions of the plurality of phalanges regions.

Broadly stated, in some embodiments, the first dorsal compressible protrusion and the second dorsal compressible protrusion can be connected by a dorsal connecting material.

Broadly stated, in some embodiments, the at least one compressible protrusion can comprise one or more of a group comprising rubber, thermoplastic rubber, foam rubber, polyurethane rubber, silicone rubber, thermoplastic resin and thermoplastic elastomer.

Broadly stated, in some embodiments, the glove can comprise at least one pressure sensor which can be disposed between the glove and the at least one compressible protrusion.

Broadly stated, e embodiments, the glove can comprise a microcontroller, the microcontroller can comprise: a processor; at least one memory module; at least one communication module; an analog to digital converter; and a power supply, wherein the at least one pressure sensor can be operatively coupled to the analog to digital converter.

Broadly stated, in some embodiments, the glove can further comprise further comprising weights disposed on one or both of a back of the glove and a backside of one or more digits of the glove.

Broadly stated, in some embodiments, a shoe can be provided for enhancing the effects of physical exercise for a person, the shoe can comprise at least one compressible protrusion which can be disposed on the shoe extending outwardly from the shoe.

Broadly stated, in some embodiments, the shoe can comprise a sole region and the at least one compressible protrusion can extend outwardly from the sole region.

Broadly stated, in some embodiments, the shoe can comprise an instep region and the at least one compressible protrusion can extend outwardly from the instep region.

Broadly stated, in some embodiments, the shoe can comprise a plurality of toe regions and the at least one compressible protrusion can extend outwardly from at least one of the plurality of toe regions.

Broadly stated, in some embodiments, each of the plurality of toe regions can comprise a tiptoe region and the at least one compressible protrusion can extend outwardly from at least one of the tiptoe regions of the plurality of toe regions.

Broadly stated, in some embodiments, each of the plurality of toe regions can comprise a sole toe region and the at least one compressible protrusion can comprise a first sole toe compressible protrusion and a second sole toe compressible protrusion each can extend outwardly from at least one of the sole toe regions of the plurality of toe regions.

Broadly stated, in some embodiments, the first sole toe compressible protrusion and the second sole toe compressible protrusion can be connected by a sole toe connecting material.

Broadly stated, in some embodiments, each of the plurality of toe regions can comprise an posterior toe region and the at least one compressible protrusion can comprise a first posterior toe compressible protrusion and a second posterior toe compressible protrusion each can extend outwardly from at least one of the posterior toe regions of the plurality of toe regions.

Broadly stated, in some embodiments, the first posterior toe compressible protrusion and the second posterior toe compressible protrusion can be connected by a posterior toe connecting material.

Broadly stated, in some embodiments, the at least one compressible protrusion can comprise one or more of a group comprising rubber, thermoplastic rubber, foam rubber, polyurethane rubber, silicone rubber, thermoplastic resin and thermoplastic elastomer.

Broadly stated, in some embodiments, the shoe can comprise at least one pressure sensor can be disposed between the shoe and the at least one compressible protrusion.

Broadly stated, in some embodiments, the shoe can comprise a microcontroller, the microcontroller can comprise: a processor; at least one memory module; at least one communication module; an analog to digital converter; and a power supply, wherein the at least one pressure sensor can be operatively coupled to the analog to digital converter.

Broadly stated, in some embodiments, a shoe can be provided for enhancing the effects of physical exercise for a person, the shoe comprising a sole further comprising a ball portion, a heel portion and a remainder portion, the improvement comprising: at least one first compressible protrusion disposed on one or both of the ball portion and the heel portion, extending downwardly therefrom; and at least one second compressible protrusion disposed on the remainder portion, extending downwardly therefrom.

Broadly stated, in some embodiments, the at least one first compressible protrusion can be larger in volume than the at least one second compressible protrusion.

Broadly stated, in some embodiments, the weight lifting shoe can comprise at least one third compressible protrusion, extending downwardly therefrom.

Broadly stated, in some embodiments, the at least one third compressible protrusion can be substantially hemispherical in configuration, and can further be smaller in diameter than one or both of the at least one first compressible protrusion and the at least one second compressible protrusion.

Broadly stated, in some embodiments, the shoe can be a cycling shoe and the sole region can further comprise a ball portion and the at least one compressible protrusion can comprise at least one first compressible protrusion disposed on the ball portion, extending downwardly therefrom, the at least one first compressible protrusion can be configured to contact the pedal of a bicycle.

Broadly stated, in some embodiments, the ball portion can further comprise a cleat for use with a clipless pedal system and the at least one first compressible protrusion can be positioned around the cleat such that the at least one first compressible protrusion contacts a pedal of the clipless pedal system when the cleat is engaged with the pedal.

Broadly stated, in some embodiments, an improved insole can be provided for a shoe for enhancing the effects of physical exercise for a person, the insole comprising an upward-facing surface and a downward-facing surface, the improvement comprising at least one compression member disposed on the downward-facing surface, extending downwardly therefrom.

Broadly stated, in some embodiments, an improved workout mat can be provided for enhancing the effects of physical exercise for a person, the mat comprising an upward-facing surface and a downward-facing surface, the improvement comprising: at least one first compression member disposed on the upward-facing surface, extending upwardly therefrom; and at least one second compression member disposed on the upward-facing surface, extending upwardly therefrom.

Broadly stated, in some embodiments, an improved bar wrap can be provided for use with free weights or exercise equipment comprising a bar or a handle, the improved bar wrap for enhancing the effects of physical exercise for a person, the improved bar wrap comprising an equipment side for contacting the bar or handle and a user side for the person to grip once the wrap has been wrapped onto the bar or the handle, the improvement comprising: at least one first compression member disposed on the downward-facing surface, extending downwardly therefrom; and at least one second compression member disposed on the downward-facing surface, extending downwardly therefrom.

Broadly stated, in some embodiments, an improved joint wrap can be provided for enhancing the effects of physical exercise for a person, the wrap comprising an elastic tube configured for placement on an elbow or a knee of the person, the improvement comprising at least one compression member disposed on the elastic tube, extending outwardly therefrom.

Broadly stated, in some embodiments, an improved workout garment can be provided for enhancing the effects of physical exercise for a person, the workout garment comprising an inner surface and an outer surface, the improvement comprising at least one compression member disposed on the outer surface, extending outwardly therefrom.

Broadly stated, in some embodiments the garment can be configured as a suit covering both an upper body portion and a lower body portion of a person.

Broadly stated, in some embodiments, the at least one first compression member can be substantially hemispherical in configuration.

Broadly stated, in some embodiments, the at least one compression member can be removably attached to the outer surface.

Broadly stated, in some embodiments, the improved workout garment can comprise at least one pocket on the outer surface wherein the at least one compression member can be removably attached to the outer surface by inserting the at least one compression member into the pocket.

Broadly stated, in some embodiments, the garment can be fitted to a lower body portion of the person.

Broadly stated, in some embodiments, the garment can be fitted to an upper body portion of the person.

Broadly stated, in some embodiments, the inner surface and the outer surface can further comprise a hood portion wherein the at least one compression member is disposed on the hood portion.

Broadly stated, in some embodiments, the at least one compressible member can removably attached to the inner surface and extends downward along the inner surface so as to be positioned along the intergluteal cleft of the person.

Broadly stated, in some embodiments, the at least one first compression member can comprise one or more of a group comprising rubber, thermoplastic rubber, foam rubber, polyurethane rubber, silicone rubber, thermoplastic resin and thermoplastic elastomer.

Broadly stated, in some embodiments, the garment can further comprise weights disposed thereon.

Broadly stated, in some embodiments, the weights can be disposed on a limb portion of the garment.

Broadly stated, in some embodiments, an improved workout sock can be provided for enhancing the effects of physical exercise for a person, the foot covering comprising an inner surface and an outer surface, the improvement comprising at least one compression member disposed on the outer surface, extending outwardly therefrom.

Broadly stated, in some embodiments, the at least one first compression member can be substantially hemispherical in configuration.

Broadly stated, in some embodiments, one or both of the at least one first compression member and the at least one second compression member can comprise one or more of a group comprising rubber, thermoplastic rubber, foam rubber, polyurethane rubber, silicone rubber, thermoplastic resin and thermoplastic elastomer.

Broadly stated, in some embodiments, an improved shoe cover can be provided for enhancing the effects of physical exercise for a person, the foot covering comprising an inner surface and an outer surface, the improvement comprising at least one compression member disposed on the outer surface, extending outwardly therefrom.

Broadly stated, in some embodiments, the at least one first compression member can be substantially hemispherical in configuration.

Broadly stated, in some embodiments, one or both of the at least one first compression member and the at least one second compression member can comprise one or more of a group comprising rubber, thermoplastic rubber, foam rubber, polyurethane rubber, silicone rubber, thermoplastic resin and thermoplastic elastomer.

Broadly stated, in some embodiments, an improved floor covering can be provided for enhancing the effects of physical exercise for a person, the floor covering comprising an upward-facing surface and a downward-facing surface, the improvement comprising at least one first compression member disposed on the upward-facing surface, extending upwardly therefrom; and at least one second compression member disposed on the upward-facing surface, extending upwardly therefrom.

Broadly stated, in some embodiments, one or both of the at least one first compression member and the at least one second compression member can be substantially hemispherical in configuration.

Broadly stated, in some embodiments, the at least one first compression member can be larger in volume than the at least one second compression member.

Broadly stated, in some embodiments, one or both of the at least one first compression member and the at least one second compression member can comprise one or more of a group comprising rubber, thermoplastic rubber, foam rubber, polyurethane rubber, silicone rubber, thermoplastic resin and thermoplastic elastomer.

Broadly stated, in some embodiments, a shoe can be provided for enhancing proprioceptive feedback to a person, the shoe can comprise: a sole portion which can comprise a sole inner surface, a toe region and one or more inter-toe compressible members; and an upper portion which can comprise an upper inner surface, the sole inner surface and the upper inner surface can define a foot cavity for receiving the foot of the user, and the one or more inter-toe compressible members can be coupled to and extend upwards from the inner surface of toe region of the sole to the inner surface of the upper, the one or more inter-toe compressible members can be configured to fit between the toes of the person when the person's foot is placed inside the shoe.

Broadly stated, in some embodiments, an insole can be provided for enhancing proprioceptive feedback to a person, the insole can be configured to fit inside a shoe, the insole can comprise: an upper surface; a toe region; and one or more inter-toe compressible members, the one or more inter-toe compressible members can be coupled to and extend upwards from the upper surface of toe region of the insole, the one or more inter-toe compressible members can be configured to fit between the toes of the person when the person's foot is placed inside the shoe containing the insole.

Broadly stated, in some embodiments, a sock can be provided for enhancing proprioceptive feedback to a person, the sock can comprise: an instep region; and two or more toe regions which can be coupled to the instep region and configured to receive at least one toe of the person; and one or more inter-toe compressible members, the one or more inter-toe compressible members can be coupled to each of the adjacent two or more toe regions one or more inter-toe compressible members.

Broadly stated, in some embodiments, an improved pedal for a bicycle can be provided, the pedal can comprise a spindle; and a housing, the housing can comprise a platform, the improvement can comprise at least one compression member disposed on the platform, extending upwardly therefrom.

Broadly stated, in some embodiments, an insert for shoe can be provided for providing a proprioceptive effect on a person wearing the shoe, the insert comprising a loop of a compressible material that can be configured in the shape of a shoe insole so that the loop can be inserted and disposed around an interior perimeter within the shoe, the loop comprising: a toe perimeter portion; an outer perimeter portion; a heel portion; and an inner perimeter portion.

Broadly stated, in some embodiments, a shoe can be provided for providing a proprioceptive effect on a person wearing the shoe, the shoe comprising an insert further comprising a loop of a compressible material that can be configured in the shape of a shoe insole so that the loop can be inserted and disposed around an interior perimeter within the shoe, the loop comprising: a toe perimeter portion; an outer perimeter portion; a heel portion; and an inner perimeter portion.

Broadly stated, in some embodiments, the inner perimeter portion can further comprise an arch support.

Broadly stated, in some embodiments, the heel portion can further comprise an elevated heel support.

Broadly stated, in some embodiments, the insert can further comprise a toe cap disposed on the toe perimeter portion, wherein the toe cap is configured to cover at least a portion of at least one of the person's toes when wearing the shoe with the insert disposed therein.

Broadly stated, in some embodiments, the toe cap can further comprise at least one toe divider extending downwardly therefrom, and configured to separate at least one pair of toes of the person when wearing the shoe with the insert disposed therein.

Broadly stated, in some embodiments, the compressible material can be comprised of one or more of a group comprising rubber, thermoplastic rubber, foam rubber, polyurethane rubber, silicone rubber, thermoplastic resin and thermoplastic elastomer.

Broadly stated, in some embodiments, the shoe can further comprise at least one protrusion extending downwardly from a sole of the shoe, the at least one protrusion comprised of the compressible material.

Broadly stated, in some embodiments, the shoe can further comprise at least one pressure sensor disposed between the shoe and the at least one protrusion, or within the at least one protrusion.

Broadly stated, in some embodiments, the shoe can further comprise a microcontroller, the microcontroller comprising: a processor; at least one memory module; at least one communication module; an analog to digital converter; and a power supply, wherein the at least on pressure sensor is coupled to the analog to digital converter.

Broadly stated, in some embodiments a shoe can be provided for enhancing proprioceptive feedback to a person wearing the shoe, the shoe comprising a sole; an upper disposed on the sole; a strap comprising a first end and a second end, the first end operatively attached to a lateral edge of the sole, the strap configured to move from a first position wherein the strap wraps over the upper, wherein the second end comprises a fastener for fastening to the upper and wherein the second fastens to the upper, to a second position where the strap wraps under the sole, wherein the second end fastens to the upper; and a plurality of compressible members disposed on the strap.

Broadly stated, in some embodiments, the fastener on the shoe can comprise one or more of a group comprising of hook and loop fasteners, snaps, buttons and buckles.

Broadly stated, in some embodiments, the shoe can further comprise a heel compressible member configured for removably attaching to a heel of the shoe.

Broadly stated, in some embodiments, a sports helmet can be provided for providing proprioceptive feedback to a person's head when the person is wearing the helmet, the helmet comprising: an outer shell comprising a cavity therein; an inner liner disposed in the cavity and configured to receive the head; and at least one compressible member disposed on the inner liner, wherein the at least compressible member contacts the head when the person places the helmet on their head.

Broadly stated, in some embodiments, the at least one compressible member can be disposed on one or more of a forehead portion, a rear portion, a top portion and side portions of the liner.

Broadly stated, in some embodiments, an improved free weight comprising a pair of end weights and a handle disposed therebetween can be provided, the improvement comprising a plurality of compressible members disposed on an external surface of the handle.

Broadly stated, in some embodiments, the plurality of compressible members can be disposed on the handle in one or more arrangements comprising a circumferential arrangement around the handle, a spiral arrangement around the handle, and a cross-hatch pattern around the handle.

Broadly stated, in some embodiments, at least one of the plurality of compressible members can be hemispherical-shaped.

Broadly stated, in some embodiments, at least one of the plurality of compressible members can be comprised of one or more of a group comprising rubber, thermoplastic rubber, foam rubber, polyurethane rubber, silicone rubber, thermoplastic resin and thermoplastic elastomer in any of the foregoing described embodiments.

### BRIEF DESCRIPTION OF THE DRAWINGS

FIG. 1 is a top plan view depicting one embodiment of a pair of weight lifting gloves with compressible hemispherical material on the palm and digits of the gloves.

FIG. 2 is a perspective view depicting sections of a sphere of compressible material for use with the weight lifting gloves of FIG. 1.

FIG. 3 is a side elevation view depicting one embodiment of a weight lifting shoe with compressible hemispherical material on the sole of the shoe.

FIG. 4 is a bottom plan view depicting the sole of the weight lifting shoe of FIG. 3.

FIG. 5 is a perspective view depicting sections of a sphere of compressible material for use with the weight lifting shoe of FIG. 3.

FIG. 6 is a perspective view depicting one embodiment of a galosh on a show, the galosh comprising compressible hemispherical material on the sole of the shoe.

FIG. 7 is a bottom plan view depicting the sole of the galosh of FIG. 6.

FIG. 8 is a top plan view depicting one embodiment of a pair of running gloves with compressible hemispherical material on the palm and digits of the gloves.

FIG. 9 is a side elevation view depicting one embodiment of a running shoe with compressible hemispherical material on the sole of the shoe.

FIG. 10 is a bottom plan view depicting the sole of the shoe of FIG. 9.

FIG. 11 is a bottom plan view depicting one embodiment of an insole with compressible hemispherical material on the sole thereof.

FIG. 12A is a top plan view depicting one embodiment of an exercise mat with compressible hemispherical material thereon.

FIG. 12B is a perspective view depicting a second embodiment of an exercise mat with compressible hemispherical material thereon.

FIG. 13 is a perspective view depicting one embodiment of a barbell wrap with compressible hemispherical material thereon, to be used with a dumbbell.

FIG. 14 is a perspective view depicting the barbell wrap of FIG. 14 being used with a barbell.

FIG. 15 is a perspective view depicting one embodiment of a joint wrap having compressible hemispherical material extending therefrom.

FIG. 16 is an elevation view depicting the joint wrap of FIG. 15 positioned on the elbows and knee of a person.

FIG. 17 is an elevation view depicting embodiments of workout garments worn by a person having compressible hemispherical material extending therefrom.

FIG. 18 is a perspective view depicting one embodiment of a workout sock comprising compressible hemispherical material extending outwardly therefrom.

FIG. 19 is a side elevation view depicting one embodiment of a shoe cover with compressible hemispherical material extending outwardly therefrom.

FIG. 20 is a rear elevation depicting the shoe cover of FIG. 4.

FIG. 21 is a top plan view depicting one embodiment of a floor covering with compressible hemispherical material thereon.

FIG. 22 is a perspective view depicting one embodiment of a headband having compressible hemispherical material extending therefrom.

FIG. 23A is an elevation view depicting one embodiment of an exercise glove having compressible protrusions extending therefrom.

FIG. 23B is an elevation view depicting the exercise glove of FIG. 23A.

FIG. 24 is an elevation view depicting one embodiment of an exercise glove having compressible inter-phalange compressible members.

FIG. 25 is a block diagram depicting an embodiment of a microcontroller connected to pressure sensors.

FIG. 26 is a flowchart depicting a method collecting data from pressure sensors.

FIG. 27 is a perspective view depicting one embodiment of a pair of exercise shoes with compressible hemispherical protrusions on the instep and toes of the shoes.

FIG. 28 is a perspective view depicting one embodiment of a pair of shoes with inter-toe compressible members.

FIG. 29 is a perspective view depicting one embodiment of a pair of insoles with inter-toe compressible members.

FIG. 30 is a perspective view depicting one embodiment of a pair of socks with inter-toe compressible members.

FIG. 31A is a perspective view depicting one embodiment of a lower body workout garment with an intergluteal cleft compressible member.

FIG. 31B is a top perspective view depicting the workout garment of FIG. 31a with the compressible member inserted into a pocket on an interior surface of the garment.

FIG. 31C is a top perspective view depicting the workout garment of FIG. 31b with the compressible member removed from the pocket.

FIG. 32 is a bottom plan view depicting the sole of a cycling shoe with compressible members protruding from a ball portion of the shoe, the compressible members positioned around a cleat of the cycling shoe.

FIG. 33 is a perspective view depicting a bicycle pedal with compressible members protruding upwardly from the pedal.

FIG. 34 is a top plan view depicting one embodiment of a pair of shoe inserts with compressible material disposed around its perimeter.

FIG. 35 is a perspective view depicting the shoe inserts of FIG. 34.

FIG. 36 is a top plan view depicting a second embodiment of a pair of shoe inserts with compressible material disposed around its perimeter and a toe cap.

FIG. 37 is a perspective view depicting the shoe inserts of FIG. 36.

FIG. 38 is a front perspective transparent view depicting a shoe with the shoe insert of FIG. 36.

FIG. 39 is a side perspective view depicting the shoe of FIG. 38.

FIG. 40 is a side elevation plan view depicting a pair of shoe with compressible protrusions disposed on the soles thereof.

FIG. 41 is a front perspective view depicting another embodiment of a shoe insert having compressible members disposed at a toe and at a heel portions thereof.

FIG. 42 is a side perspective view depicting the shoe insert of FIG. 41.

FIG. 43 is a top perspective view depicting the shoe insert of FIG. 41.

FIG. 44 is a front perspective view depicting one embodiment of a full-body workout suit with a plurality of compressible members disposed thereon.

FIG. 45 is a rear perspective view depicting the full-body workout suit of FIG. 44.

FIG. 46 is a perspective view depicting a first embodiment of a dumbbell having compressible members disposed around the handle of the dumbbell.

FIG. 47 is a perspective view depicting a second embodiment of a dumbbell having compressible members disposed around the handle of the dumbbell.

FIG. 48 is a perspective view depicting a third embodiment of a dumbbell having compressible members disposed around the handle of the dumbbell.

FIG. 49 is a perspective view depicting a fourth embodiment of a dumbbell having compressible members disposed around the handle of the dumbbell.

FIG. 50 is a left side elevation view depicting one embodiment of a left convertible cross-training shoe having a movable strap with compressible members disposed thereon.

FIG. 51 is a rear elevation view depicting the cross-training shoe of FIG. 50.

FIG. 52 is a right side elevation view depicting the cross-training shoe of FIG. 50.

FIG. 53 is a perspective view depicting an alternate embodiment of a pair of convertible cross-training shoes having a movable strap with compressible members and weights disposed thereon.

FIG. 54 is a bottom plan view depicting a sport helmet having compressible members disposed therein.

### DETAILED DESCRIPTION OF THE INVENTION

In this description, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the present technology can include a variety of combinations and/or integrations of the embodiments described herein.

In some embodiments, a compressible protrusion can be provided. The compressible protrusion can comprise a planar surface and a protrusion from said planar surface. The compressible protrusion can be configured to be disposed between a person and a piece of exercise equipment or any hard surface. The compressible protrusion can be configured such that it can be attached to a shoe, glove, garment, sock, shoe cover or other exercise apparatus.

In some embodiments, the compressible protrusion can comprise a suction cup or adhesive coupled to the planar surface. The compressible protrusion can then be fixed to a surface using the suction cup or adhesive.

In some embodiments including those described herein, the compressible protrusions can improve the user's body positioning when performing exercises or other activities. The compressible protrusions can cause the user to actively hold the muscles, joints and body in a proper alignment providing proprioceptive feedback to the CNS. These voluntary movements can be repeated and stored as central commands. This patterning of the brain allows various skills to be performed without continuous without continuous reference to consciousness and can increase the conscious and unconscious awareness of the joint or limb in motion.

In some embodiments, including those described herein, the compressible protrusions can be comprised of an elastomeric material that has physical properties that enable it to be compressed under force and to substantially return to its original shape when the force is released. Such materials can include rubber, thermoplastic rubber, foam rubber, polyurethane rubber, silicone rubber, thermoplastic resin, thermoplastic elastomers and any other material having similar physical properties as well known to those skilled in the art. In further embodiments, the exterior of the compressible hemisphere can be composed of a durable material, such as plastic or synthetic fiber and the interior of the compressible protrusion can comprise one or more of a liquid, a gel and a gas, such as air.

Though the compressible protrusions in this application are at times described as hemispheres, for the purposes of this specification and the claims herein, it shall be understood that any compressible protrusion described as a hemisphere or as being hemispherical can be substituted with other shapes such as a hemi-ovoid, hemi-ellipsoid, tetrahedron, trapezoidal prism or other similarly curved or polyhedral surface, or other suitable shape as well known to those skilled in the art.

Gloves can be provided which comprise at least one compressible protrusion. In configuring gloves in this manner, instability can be created when the protrusion is located between the users hand and a surface such as when gripping a barbell or dumbbell, or other like weight/resistance equipment, performing floor exercises or other stretching activities, or squeezing the protrusion with the fingers to enable exercise of muscles in the fingers and forearms while running or other lower body activity, which can allow additional muscles to be used during a weight lifting exercise without comprising the joints of the person lifting the weight. This can also cause the user to actively hold the muscles, joints and body in a proper alignment providing proprioceptive feedback to the CNS. These voluntary movements can be repeated and stored as central commands. This patterning of the brain allows various skills to be performed without continuous without continuous reference to consciousness and can increase the conscious and unconscious awareness of the joint or limb in motion.

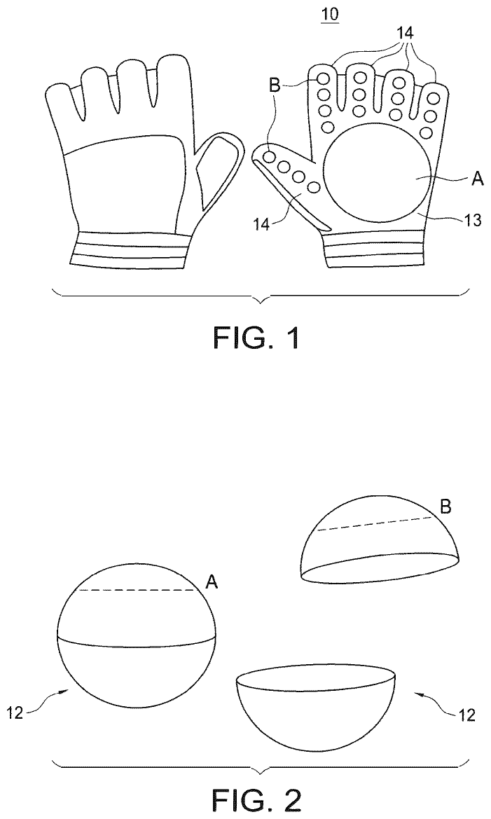

Referring to FIG. 1, one embodiment of improved weight lifting glove 10 is shown. In some embodiments, glove 10 can be configured to cover portions of the anterior or palmar region and portions of the posterior or dorsum of the hand such as the metacarpus and one or more fingers and optionally anterior and posterior portions of the wrist of a user's hand. In this embodiment, glove 10 can comprise an anterior region 13 adapted to cover the front or palmar region of a user's hand. Anterior region 13 can comprise anterior compressible hemisphere A coupled to and positioned on the exterior surface of anterior region 13. Each phalange region 14, can extend outwardly from the anterior region 13 and can comprise an anterior phalange region 14 coupled to or integral with and extending outwardly from the anterior region 13 and can comprise one or more anterior phalange compressible hemisphere B coupled to and positioned on the exterior surface of anterior phalange region 14.

Referring to FIG. 2, an example of how hemispheres A and B can be formed is shown by taking sections of sphere 12.

In configuring gloves 10 in this manner, instability can be created when gripping a barbell or dumbbell, or other like weight/resistance equipment, which can allow additional muscles to be used during a weight lifting exercise without comprising the joints of the person lifting the weight. This can also cause the user to actively hold the muscles, joints and body in a proper alignment providing proprioceptive feedback to the CNS. These voluntary movements can be repeated and stored as central commands. This patterning of the brain allows various skills to be performed without continuous without continuous reference to consciousness and can increase the conscious and unconscious awareness of the joint or limb in motion.

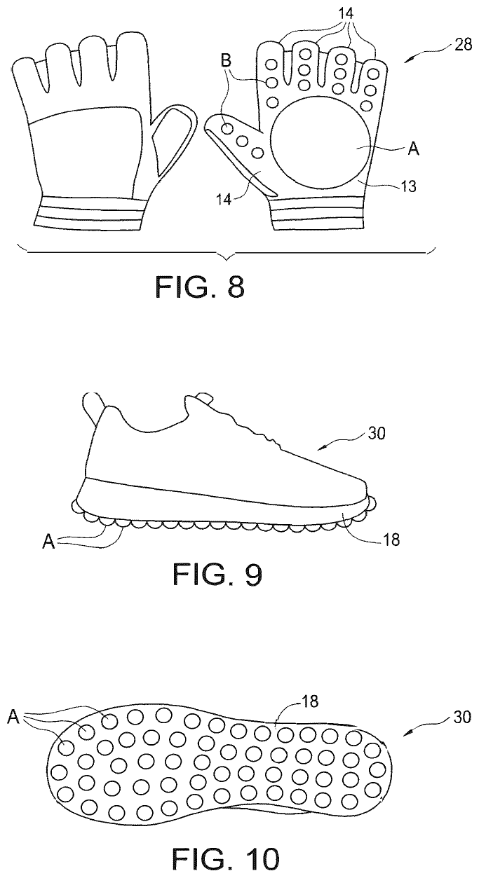

Referring to FIG. 8, one embodiment of improved running gloves 28 is shown. In some embodiments, palm 13 of gloves 28 can comprise compressible hemisphere A, and one or more compressible hemispheres B along digits 14 of gloves 28. Hemispheres A and B disposed on gloves 28 can be comprised of the elastomeric or other durable material discussed above. Gloves 28 can be worn while running such that the runner can squeeze the gloves to enable exercise of muscles in the fingers and forearms at the same time.

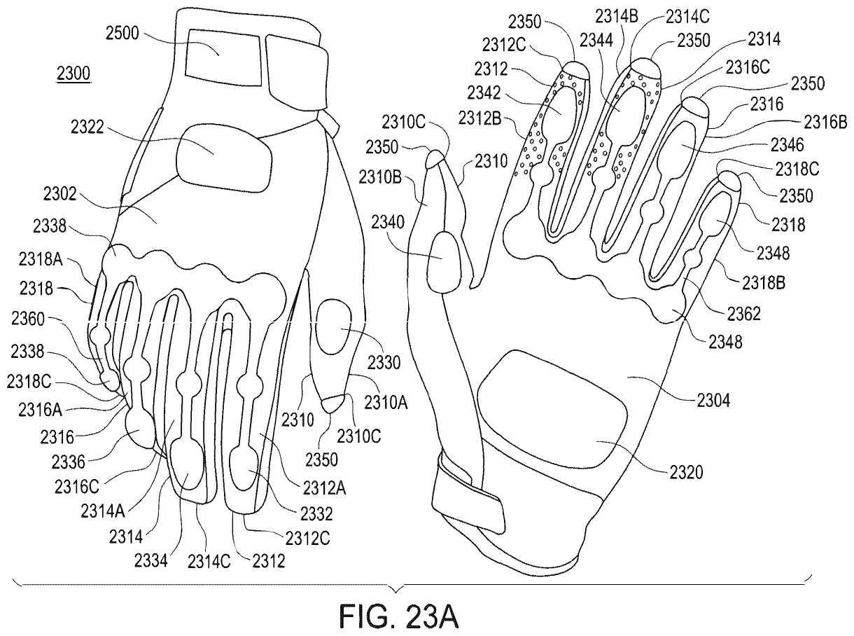

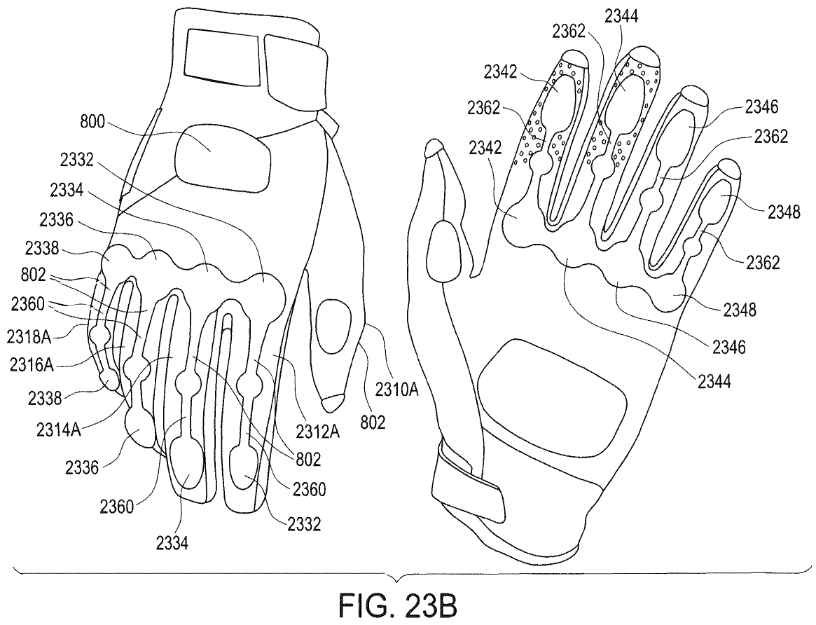

Referring to FIGS. 23A and 23B, a further embodiment of an exercise glove is shown. Glove 2300 can be configured to cover portions of the anterior or palmar region and portions of the posterior or dorsum of the hand such as the metacarpus and one or more fingers and optionally anterior and posterior portions of the wrist of a user's hand. In this embodiment, glove 2300 can comprise dorsal region 2302 adapted to cover the back or dorsum of a user's hand. Dorsal region 2302 can comprise dorsal protrusion 2320 coupled to and positioned on the exterior surface of dorsal region 2302. One or more phalange regions 2310, 2312, 2314, 2316, and 2318, configured to receive a finger of a hand can be coupled to or integral with the dorsal region 2302. In some embodiments, thumb phalange region 2310 can be configured to receive the thumb or a user, index phalange region 2312 can be configured to receive the index finger of a user, a middle phalange region 2314 can be configured to receive the middle finger of a user, a ring phalange region 2316 can be configured to receive the ring finger of a user, and a little phalange region 2318 can be configured to receive the little finger of a user.

Each phalange region 2310, 2312, 2314, 2316, and 2318, can comprise a posterior phalange region such as posterior thumb phalange region 2310A, posterior index phalange region 2312A, posterior middle phalange region 2314A, posterior ring phalange region 2316A, and posterior little phalange region 2318A, coupled to and extending outwardly from the dorsal region 2302. Posterior thumb phalange region 2310A can extend outwardly from the dorsal region 2302 and can comprise one or more posterior thumb phalange protrusions 2330 coupled to and positioned on the exterior surface of posterior thumb phalange region 2310A. Posterior index phalange region 2312A can be disposed adjacent to thumb phalange region 2310, and posterior index phalange region 2312A can comprise one or more posterior index phalange protrusions 2332 coupled to and positioned on the exterior surface of posterior index phalange region 2312A. Posterior middle phalange region 2314A can be disposed adjacent to index phalange region 2312, and posterior middle phalange region 2314A can comprise one or more posterior middle phalange protrusions 2334 coupled to and positioned on the exterior surface of posterior middle phalange region 2314A. Posterior ring phalange region 2316A can be disposed adjacent to middle phalange region 2314, and posterior ring phalange region 2316A can comprise one or more posterior ring phalange protrusions 2336 coupled to and positioned on the exterior surface of posterior ring phalange region 2316A. Posterior little phalange region 2318A can be disposed adjacent to ring phalange region 2316, and posterior little phalange region 2318A can comprise one or more posterior little phalange protrusions 2338 coupled to and positioned on the exterior surface of posterior little phalange region 2318A.

In some embodiments, where there are two or more posterior phalange protrusions, posterior connecting material 2360 can extend from a first posterior phalange protrusion to a second posterior phalange protrusion. The posterior connecting material 2360 can be coupled to and extend along the exterior surface of the posterior phalange region 2310A, 2312A, 2314A, 2316A, or 2318A. The posterior connecting material 2362 can comprise the same materials used for the posterior phalange protrusions 2330, 2332, 2334, 2336, and 2338, as described above. The posterior connecting material can provide additional resistance when the user flexes its fingers which can require additional effort by the user.

Glove 2300 can comprise an anterior region 2304 adapted to cover the front or palmar region of a user's hand. Anterior region 2304 can comprise anterior protrusion 2320 coupled to and positioned on the exterior surface of anterior region 2304. Each phalange region 2310, 2312, 2314, 2316, and 2318, can extend outwardly from the dorsal region 2302 and can comprise an anterior phalange region such as anterior thumb phalange region 2310B, anterior index phalange region 2312B, anterior middle phalange region 2314B, anterior ring phalange region 2316B, and anterior little phalange region 2318B, coupled to or integral with and extending outwardly from the anterior region 2304. Anterior thumb phalange region 2310B can extend outwardly from the anterior region 2304 and can comprise one or more anterior thumb phalange protrusions 2340 coupled to and positioned on the exterior surface of anterior thumb phalange region 2310B. Anterior index phalange region 2312B can be disposed adjacent to thumb phalange region 2310, and anterior index phalange region 2312B can comprise one or more anterior index phalange protrusions 2342 coupled to and positioned on the exterior surface of anterior index phalange region 2312B. Anterior middle phalange region 2314B can be disposed adjacent to index phalange region 2312, and anterior middle phalange region 2314B can comprise one or more anterior middle phalange protrusions 2344 coupled to and positioned on the exterior surface of anterior middle phalange region 2314B. Anterior ring phalange region 2316B can be disposed adjacent to middle phalange region 2314, and anterior ring phalange region 2316B can comprise one or more anterior ring phalange protrusions 2346 coupled to and positioned on the exterior surface of anterior ring phalange region 2316B. Anterior little phalange region 2318B can be disposed adjacent to ring phalange region 2316, and anterior little phalange region 2318B can comprise one or more anterior little phalange protrusions 2348 coupled to and positioned on the exterior surface of anterior little phalange region 2318B.

In some embodiments, where there are two or more anterior phalange protrusions, anterior connecting material 2362 can extend from a first anterior phalange protrusion to a second anterior phalange protrusion. The anterior connecting material 2362 can be coupled to and extend along the exterior surface of the anterior phalange region 2310B, 2312B, 2314B, 2316B, or 2318. The anterior connecting material 2362 can comprise the same materials used for the anterior phalange protrusions 2340, 2342, 2344, 2346, and 2348, as described above. The anterior connecting material can provide additional resistance when the user extends its fingers which can require additional effort by the user.

In some embodiments, each phalange region 2310, 2312, 2314, 2316, and 2318, can comprise a fingertip region such as thumb phalange fingertip region 2310C, index phalange fingertip region 2312C, middle phalange fingertip region 2314C, ring phalange region 2316C, and little phalange fingertip region 2318C. One or more of the phalange fingertip regions 2310C, 2312C, 2314C, 2316C, and 2318C can comprise fingertip protrusions 2350 coupled to and positioned on the exterior surface of phalange fingertip region 2310C, 2312C, 2314C, 2316C, and 2318C.

In some embodiments, glove 2300 can further comprise weights placed on the back of the hand or on the backside of one or more of the digits of the glove, either as separate weights that can be inserted into pockets disposed on the gloves, or that can be attached to the gloves during their manufacture. In some embodiments, weight 800 can be added or disposed on dorsal region 2302, while in other embodiments, weights 802 can be added or disposed on the posterior phalange regions 2310A, 2312A, 2314A, 2316A and 2318A. By providing weights 800 and 802 on gloves 2300, the weights, even in small amounts, can intensify the effect of exercise using free weights or resistance training equipment. The inclusion of weights 800 and 802 on gloves 2300 can reduce the amount of free weight or resistance used by the person performing the exercise thereby allowing them to move more freely without restriction in a natural and functional way, which can be more athletic in nature.

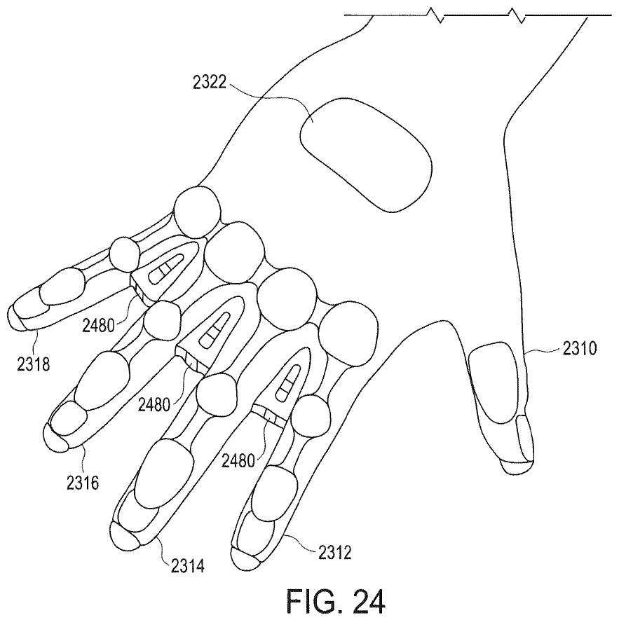

In some embodiments, as shown in FIG. 24, glove 2300 can comprise one or more inter-phalange compressible members 2480 between phalange regions 2310 and 2312, 2312 and 2314, 2314 and 2316, and 2316 and 2318. The inter-phalange compressible members 2480 can be coupled to each of the adjacent phalange regions.

In some embodiments the protrusions can be coupled to glove 2300 with heat bonding, chemical bonding, adhesives, stitching, clasp type fasteners, clip type fasteners, rivet type fasteners, threaded type fasteners, other types of fasteners, or any other suitable joining method.

In some embodiments, glove 2300 can comprise one or more pressure sensors 2580, which can measure the pressure applied to each of the protrusions. The pressure sensors 2580 can be placed between the protrusions and the exterior surface of glove 2300 or embedded within the protrusions. In some embodiments, pressure sensors 2580 can comprise one of more of the following load sensing technologies: piezoresistive sensors, piezoelectric sensors, strain gauge sensors comprise wheatstone bridges, capacitive sensors, electromagnetic sensors, optical sensors, resistive sensors and any other load sensing technology as well known by those skilled in the art including, but not limited to, pressure sensitive fabric (see http://eeonyx.com/product_category/pressure-sensors/).

Shoes can be provided which comprise at least one compressible protrusion. In configuring shoes in this manner, instability can be created when the protrusion is located between the users foot and a surface such as when standing when lifting weights, using weight/resistance equipment, performing floor exercises or other stretching activities, which can allow additional muscles to be used during a weight lifting exercise without comprising the joints of the person lifting the weight. This can also cause the user to actively hold the muscles, joints and body in a proper alignment providing proprioceptive feedback to the CNS. These voluntary movements can be repeated and stored as central commands. This patterning of the brain allows various skills to be performed without continuous without continuous reference to consciousness and can increase the conscious and unconscious awareness of the joint or limb in motion.

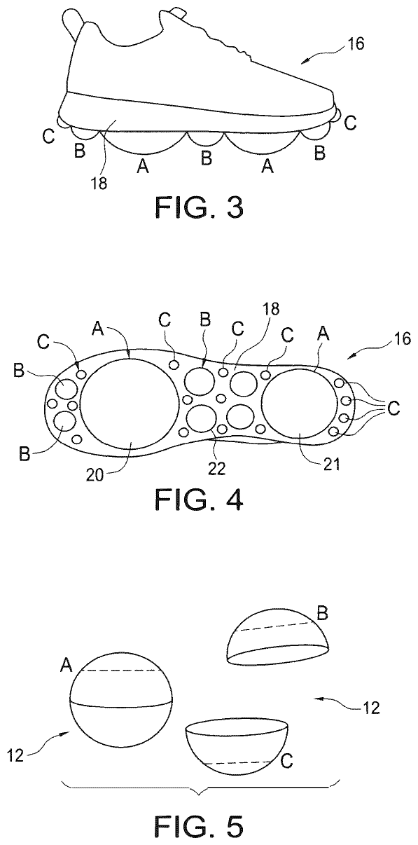

Referring to FIGS. 3 to 5, one embodiment of improved weight lifting shoe 16 is shown. In some embodiments, sole 18 of shoe 16 can comprise compressible hemisphere A disposed on ball portion 20 and heel portion 21 on sole 18. In further embodiments, sole 18 can comprise compressible hemispheres disposed on arch portion 22, and on other portions, of sole 18. In yet further embodiments, sole 18 can comprise compressible hemispheres C disposed in the interstitial spaces between hemispheres A and B, where hemisphere A can be larger in volume than hemisphere B that, in turn can be larger in volume than hemisphere C. As shown in FIG. 5, hemispheres A, B and C can be sections of notional sphere 12 comprised of the elastomeric or other durable materials as described above. In providing a weight lifting shoe in this configuration, can require the user to hold the body in proper alignment, adding proprioceptive elements to the exercise to assist in proper patterning of the CNS and to exert additional muscles to maintain balance and stability while lifting a weight as standing on hemispheres A, B and C is similar in effect to balancing on a plastic compressible dome, as well known to those skilled in the art and used in other forms of exercise.

Referring to FIGS. 9 and 10, one embodiment of improved running shoe 30 is shown. In some embodiments, sole 18 of shoe 30 can comprise a plurality of similarly sized compressible hemispheres A disposed thereon. Hemispheres A disposed on shoe 30 can be comprised of the elastomeric or other durable materials discussed above. In providing a running shoe of this configuration, a runner can exert the use of additional muscles to hold the body in proper alignment and maintain balance and stability while running, thus enhancing the effects of the physical exercise.

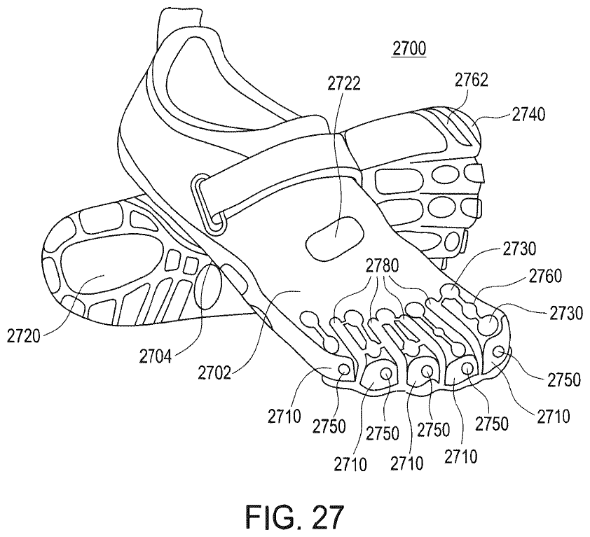

Referring to FIG. 27, an embodiment of an exercise shoe is shown. Shoe 2700 can be configured to cover portions of the sole or bottom region and portions of the instep or top of the foot. In this embodiment, the shoe 2700 can comprise instep region 2702 adapted to cover the top or instep of a user's foot. Instep region 2702 can comprise instep protrusion 2720 coupled to and positioned on the exterior surface of instep region 2702. One or more toe regions 2710, configured to receive a toe of a foot can be coupled to or integral with the instep region 2702. In some embodiments, the one or more toe regions 2710 can comprise up to five toe regions 2710, one for each toe of the user's foot.

Each toe region 2710 can comprise a posterior toe region 2710A coupled to or integral with and extending outwardly from the instep region 2702. One or more posterior toe regions 2710A can extend outwardly from the instep region 2702 and can comprise one or more posterior toe protrusions 2730 coupled to and positioned on the exterior surface of posterior toe region 2710A.

In some e embodiments, where there are two or more posterior toe protrusions 2730, posterior connecting material 2760 can extend from a first posterior toe protrusion to a second posterior toe protrusion. The posterior connecting material 2760 can be coupled to and extend along the exterior surface of the posterior toe region 2710A.

Shoe 2700 can comprise a sole region 2704 adapted to cover the sole or bottom region of a user's foot. Sole region 2704 can comprise sole protrusion 2720 coupled to and positioned on the exterior surface of sole region 2704. Each toe region 2710, can extend outwardly from the instep region 2702 and can comprise a sole toe region 2710B, coupled to or integral with and extending outwardly from the sole region 2704. Sole toe region 2710B can extend outwardly from the sole region 2704 and can comprise one or more sole toe protrusions 2740 coupled to and positioned on the exterior surface of sole toe region 2710B.

In some embodiments, where there are two or more sole toe protrusions 2740, sole connecting material 2762 can extend from a first sole toe protrusion to a second sole toe protrusion. The sole connecting material 2762 can be coupled to and extend along the exterior surface of the sole toe region 2710B.

In some embodiments, each toe region 2710 can comprise a tiptoe region 2710C. One or more of the tiptoe regions 2310C can comprise tiptoe protrusions 2750 coupled to and positioned on the exterior surface of tiptoe region 2710C.

In some embodiments, shoe 2700 can comprise one or more inter-toe compressible members 2780 between adjacent toe regions 2710. The inter-toe compressible members 2780 can be coupled to each of the adjacent toe regions 2710.

In some embodiments the protrusions can be coupled to the shoe 2700 with heat bonding, chemical bonding, adhesives, stitching, clasp type fasteners, clip type fasteners, rivet type fasteners, threaded type fasteners, other types of fasteners, or any other suitable joining method.

In some embodiments, the shoe 2700 can comprise one or more pressure sensors 2580, which can measure the pressure applied to each of the protrusions. The pressure sensors 2580 can be placed between the protrusions and the exterior surface of the shoe 2700 or embedded within the protrusions. In some embodiments, pressure sensors 2580 can comprise one of more of the following load sensing technologies: piezoresistive sensors, piezoelectric sensors, strain gauge sensors comprise wheatstone bridges, capacitive sensors, electromagnetic sensors, optical sensors, resistive sensors and any other load sensing technology as well known by those skilled in the art including, but not limited to, pressure sensitive fabric (see http://eeonyx.com/product_category/pressure-sensors/).

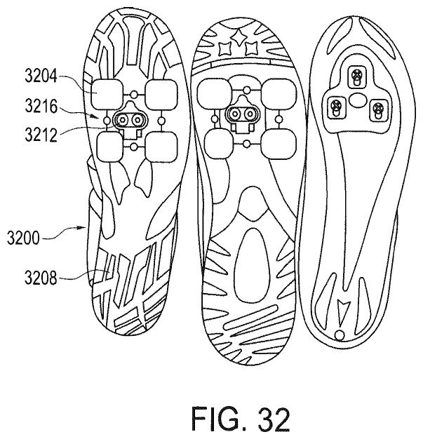

Referring to FIG. 32, an embodiment of an improved cycling shoe 3200. In some embodiments, sole 3208 of shoe 3200 can comprise one or more compressible members 3204 disposed on ball portion 3216 of sole 3208, so as to contact a pedal of a bicycle. In further embodiments, sole 3208 can comprise a cleat 3212 for use as part of a clipless pedal system. The one or more compressible members 3204 can be positioned around the cleat such that the compressible members 3204 contact the pedal of the clipless pedal system. Providing a cycling shoe in this configuration, can require the user to engage the quadriceps and hold the body in proper alignment, adding proprioceptive elements to the cycling to assist in proper patterning of the CNS and to exert additional muscles to maintain balance and stability while cycling as the compressible members 3204 can create instability.

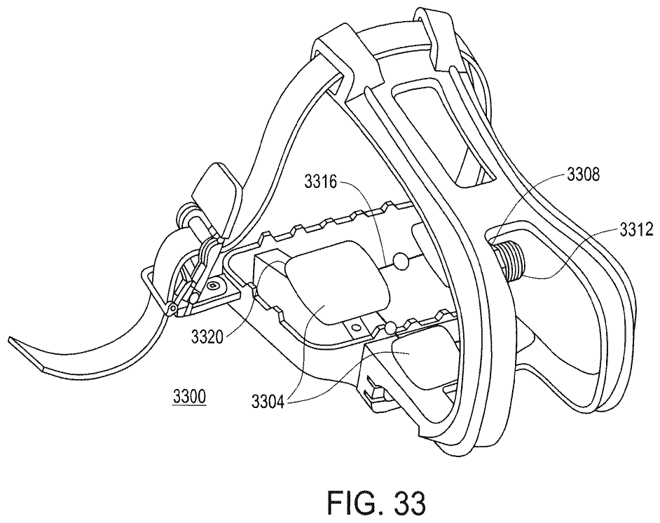

Referring to FIG. 33, an improved bicycle pedal 3300 is shown. In some embodiments pedal 3300 can comprise spindle 3308. Spindle 3308 can comprise threaded end 3312 for attaching pedal 3300 to a bicycle crank arm. Pedal 3300 can also comprise housing 3316 that rotates around spindle. Housing 3316 can comprise platform 3320 and can provide a surface for placing a shoe while operating the bicycle. Platform 3320 can comprise one or more compressible members 3304 protruding upwards from the platform 3320. Providing a bicycle pedal 3300 in this configuration, can require the user to engage the quadriceps and hold the body in proper alignment, adding proprioceptive elements to the cycling to assist in proper patterning of the CNS and to exert additional muscles to maintain balance and stability while cycling as standing on compressible members 3304 can create instability

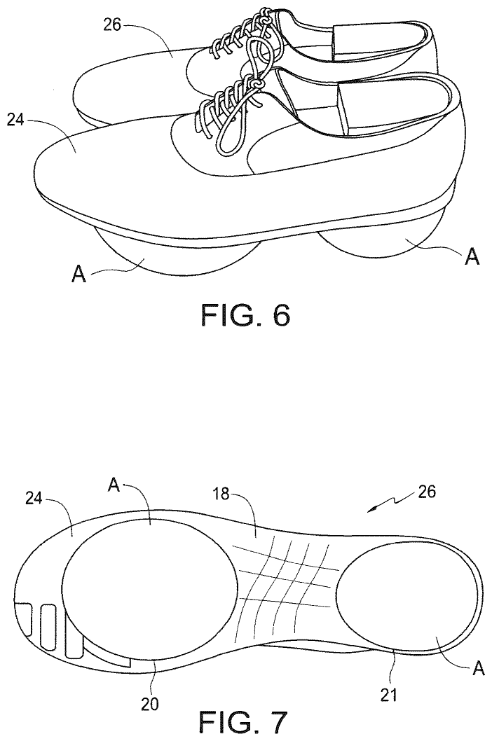

Referring to FIGS. 6 and 7, an embodiment of improved galosh 24 is shown fitted onto shoe 26. In some embodiments, sole 18 can comprise compressible hemisphere A disposed on ball portion 20 and on heel portion 21 of sole 18. In providing improved galosh 24 for use with any shoe, a person can achieve similar effects as provided by improved weight lifting shoe 16 without having a dedicated weight lifting shoe; they can simply fit galosh 24 onto any shoe the person wishes to wear. Hemispheres A used on galosh 24 can be comprised of the elastomeric or other durable material, as discussed above. Galosh 24, itself, can be comprised of rubber or Luon™, while sole 18 of galosh can be comprised of a heavier or denser material, such as plastic or a dense elastomeric material similar to those discussed above.

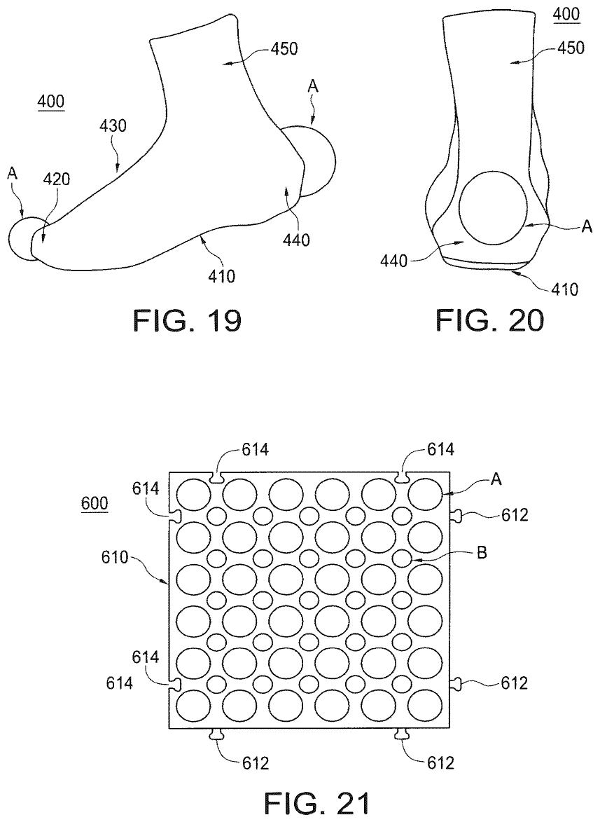

Referring to FIGS. 19 and 20, one embodiment of improved shoe cover 400 is shown. In some embodiments, shoe cover 400 can comprise one or more compressible hemispheres A disposed thereon, extending outwardly. The compressible hemispheres A can be disposed on shoe cover 400 on sole portion 410, toe portion 420, instep 430, heel portion 440 or leg portion 450. The compressible hemispheres can be comprised of the elastomeric or other durable materials as described above. Shoe cover 400 can be configured to be worn over any type of shoe. In some embodiments, shoe cover 400 can stretch to slip over a shoe worn by the user. In other embodiments, shoe cover 400 can comprise a closure means such as a zipper, or hook and loop closure along the back of leg portion to facilitate application and removal of shoe cover 400. Shoe cover 400, itself, can be comprised of nylon, polyester, neoprene or other suitably flexible material as well known to those skilled in the art. In providing a shoe cover with compressible hemispheres disposed on sole portion 410, a person standing while wearing shoe cover 400 can experience a similar effect to standing on an exercise dome and, thus, will need to hold the body in proper alignment and exert the use of additional muscles to maintain balance and stability. In providing a shoe cover with compressible hemispheres disposed on other portions of shoe cover 400, instability can be created at the contact point with the floor or exercise equipment when performing the workout which can allow additional muscles to be used and reduce strain on the joints of person. Compressible hemispheres A can be removably attached to shoe cover 400 in the same manner described with respect to the workout garments.

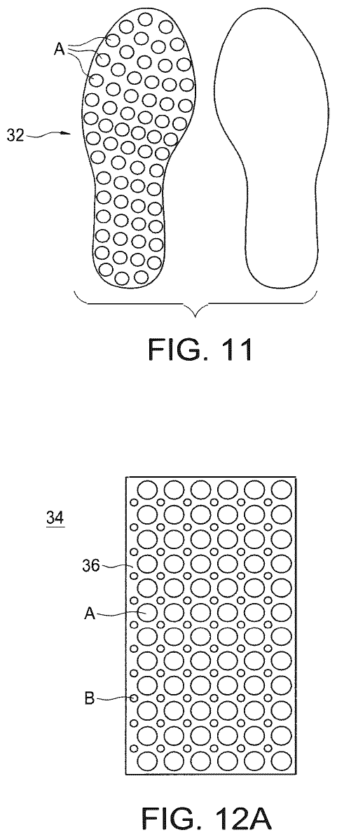

Referring to FIG. 11, one embodiment of improved shoe insole 32 is shown. In some embodiments, insole 32 can comprise a plurality of similarly sized compressible hemispheres A disposed thereon. Hemispheres A disposed on insole 32 can be comprised of the elastomeric or other durable materials discussed above. In providing an insole of this configuration that can be placed in any shoe, a person wearing such a shoe with insole 32 can experience at least some of the effects that can be provided by improved running shoes 30 discussed above.

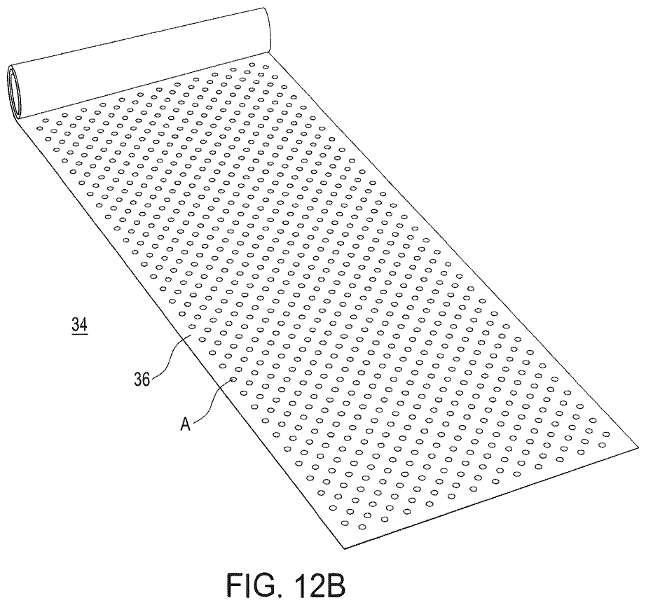

Referring to FIG. 12a, one embodiment of improved workout mat 34 is shown. In some embodiments, mat 34 can comprise base or substrate 36, further comprising a plurality of compressible hemispheres A and compressible hemispheres B disposed thereon in a spaced-apart configuration, where hemispheres A can be larger in volume than hemispheres B. In some embodiments, one or both of hemispheres A and B can be comprised of the elastomeric or other durable material discussed above. Referring to FIG. 12b, another embodiment of improved workout mat 34 is shown. In some embodiments, mat 34 can comprise base or substrate 36, further comprising a plurality of compressible hemispheres A disposed thereon in a spaced-apart configuration. In some embodiments, one or both of hemispheres A and B can be comprised of the elastomeric or other durable material discussed above. In providing an exercise mat of this configuration, a person standing or contacting the hemispheres protruding from the mat can experience a similar effect to standing on an exercise dome and, thus, will need to hold the body in proper alignment and exert the use of additional muscles to maintain balance and stability while on the mat. In some embodiments, mat 34 can be configured as a rectangle 100 cm by 180 cm.

Referring to FIG. 21, one embodiment of improved workout floor covering 600 is shown. In some embodiments, floor covering 600 can comprise base or substrate 610, further comprising a plurality of compressible hemispheres A and compressible hemispheres B disposed thereon, where hemispheres A can be larger in volume than hemispheres B. In some embodiments, one or both of hemispheres A and B can be comprised of the elastomeric or other durable material discussed above. In providing a floor covering of this configuration, a person standing or contacting the hemispheres protruding from the floor covering can experience a similar effect to standing on an exercise dome and, thus, will need to hold the body in proper alignment and exert the use of additional muscles to maintain balance and stability while on the floor covering. In some embodiments, floor covering 600 can be configured as a tile 30 cm to 100 cm square. In some embodiments the sides of the tile can comprise interlocking elements to connect with adjacent tiles. As an example of this, floor covering 600 can comprise one or more connecting tabs 612 configured to couple with tab openings 614 wherein tabs 612 of a first piece of floor covering 600 can fit into tab openings 614 of a second piece of floor covering 600 thereby interlocking them together.

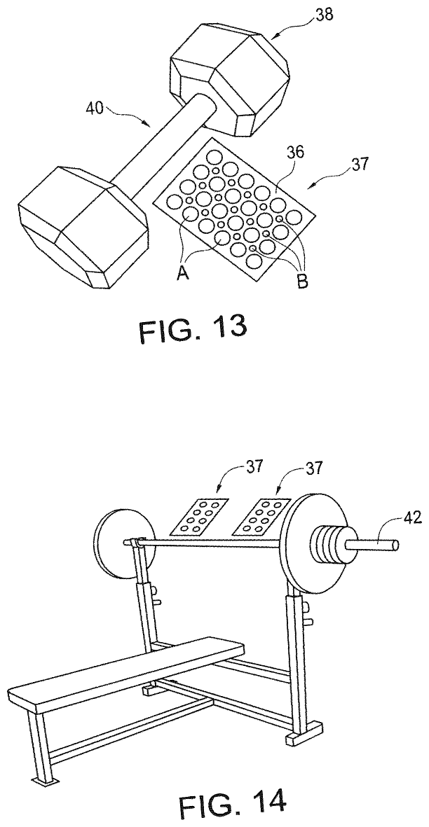

Referring to FIGS. 13 and 14, one embodiment of improved bar wrap 37 is shown. In some embodiments, wrap 37 can be a down-sized version of mat 34 that can enable a person to place wrap 37 around handle 40 of dumbbell 38 or around barbell 42. In some embodiments, wrap 37 can comprise base or substrate 36, further comprising a plurality of compressible hemispheres A and compressible hemispheres B disposed thereon, where hemispheres A can be larger in volume than hemispheres B. In some embodiments, one or both of hemispheres A and B can be comprised of the elastomeric or other durable material discussed above. In providing a barbell wrap of this configuration, and using it around handle 40 of dumbbell 38 or around barbell 42 while performing a weight lifting exercise, can cause a person to hold the body in proper alignment and use additional muscles in their hands and forearms to maintain balance, stability and control of the dumbbell or barbell during the exercise, thus, enhancing the effects of the physical exercise. Wrap 37 can also be placed around other handles such as the grip of a golf club, baseball bat, hockey stick or a racquet to provide similar benefits.

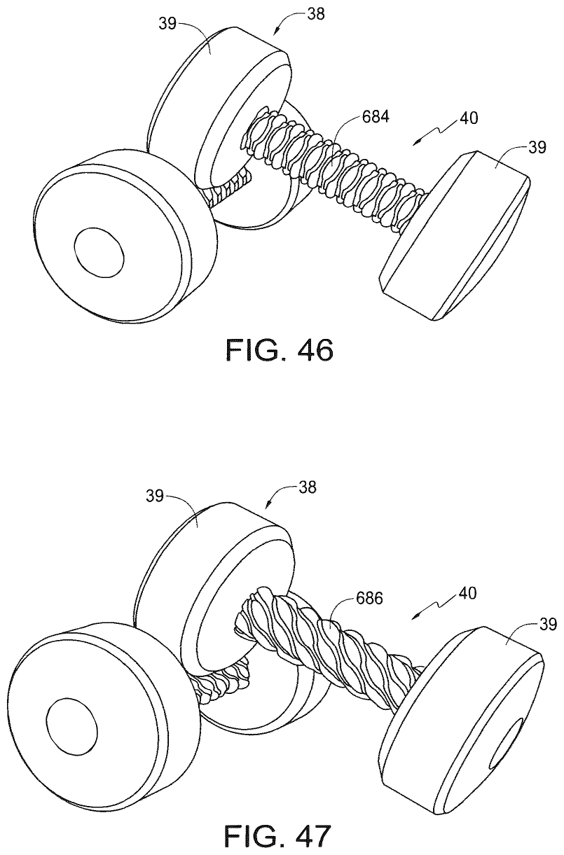

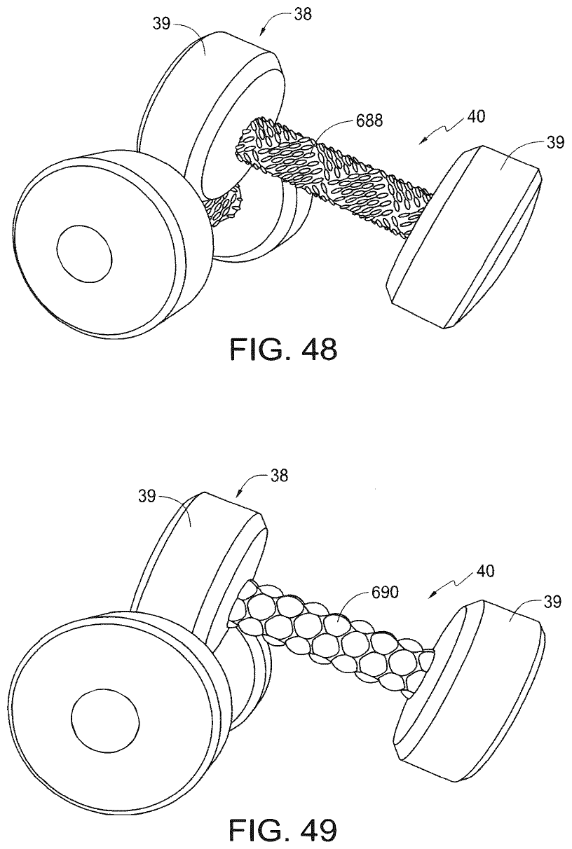

Referring to Figures alternate 46 to 49, four embodiments of free weight dumbbell 38 are shown with compressible members disposed around an external surface of handle 40 disposed between end weights 39. In FIG. 46, a first embodiment of dumbbell 38 can comprise a plurality of ellipsoid-shaped compressible members 684 arranged circumferentially around the external surface of handle 40. In FIG. 47, a second embodiment of dumbbell 38 can comprise a plurality of ellipsoid-shaped compressible members 686 arranged around the external surface of handle 40 in a spiral configuration. In FIG. 48, a third embodiment of dumbbell 38 can comprise a plurality of ellipsoid-shaped compressible members 688 configured in a cross-hatch pattern disposed around the external surface of handle 40. In FIG. 49, a fourth embodiment of dumbbell 38 can comprise a plurality of hemispherical-shaped compressible members 684 disposed circumferentially around the external surface of handle 40. In providing a dumbbell of this configuration, a separate wrap, as discussed above, would not be necessary thereby making these configurations of dumbbell more convenient to use. As with wrap 37 described above, the compressible members disposed around handle 40 of dumbbell 38 while performing a weight lifting exercise can cause a person to experience or enhance proprioceptive feedback from holding dumbbell 38, and can the person to hold their body in proper alignment and use additional muscles in their hands and forearms to maintain balance, stability and control of the dumbbell or free weight during an exercise using the weight, thus, enhancing the effects of the physical exercise.

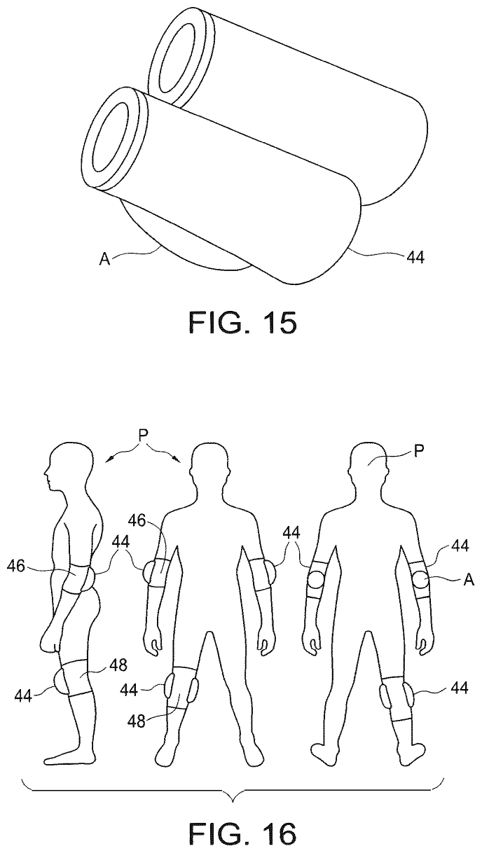

Referring to FIGS. 15 and 16, one embodiment of improved joint wrap 44 is shown. In some embodiments, joint wrap 44 can comprise one or more compressible hemisphere A disposed thereon, extending outwardly. Joint wrap 44 can be comprised of an elastic or stretchy tube of fabric that can be slipped over elbow 46 or knee 48 on person P, as shown in FIG. 16. In some embodiments, wrap 44 can comprise a single compressible hemisphere A that can be positioned over elbow 46 or over the knee cap of knee 48. In other embodiments, wrap 44 can comprise a plurality of compressible hemispheres A, where a hemisphere can extend outwardly from either side of knee 48. Compressible hemisphere A can be comprised of the elastomeric or other durable materials discussed above. In providing a joint wrap of this configuration, exercises such as “planking” or conventional floor exercises such as push-ups can be enhanced by having a compressible hemisphere placed between an elbow or knee and the floor.

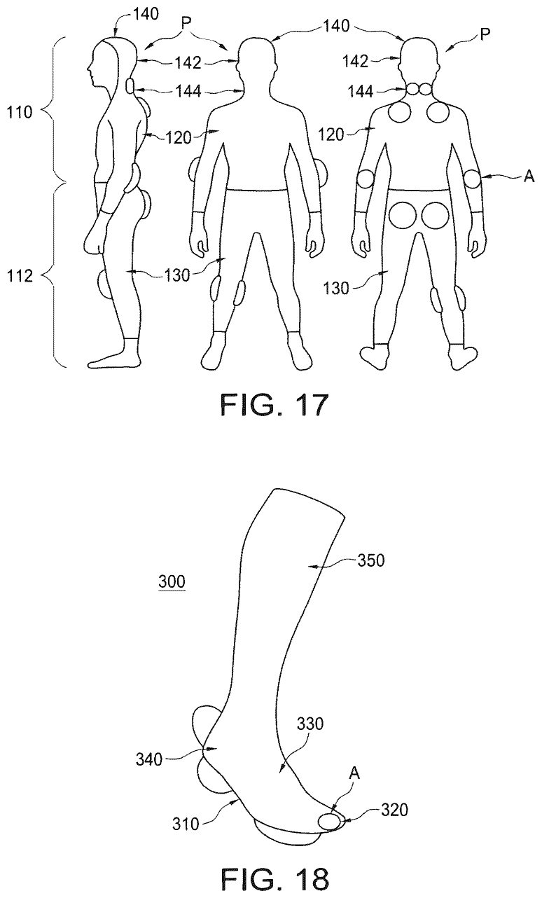

Referring to FIG. 17, two embodiments of improved workout garments are shown. Workout shirt 120 is shown on upper body portion 110 of person P and workout pants 130 are shown on lower body portion 112 of person P. In some embodiments, the improved workout garments can include garments for upper body portion 110 such as long and short sleeve shirts, tank tops, hoodies, sleeves and other upper body apparel as well as garments for lower body portion 112 such as leggings, tights, pants, shorts, socks and other lower body apparel. As shown in FIG. 17, workout shirt 120 or workout shirt 130 can comprise one or more compressible hemispheres A disposed thereon, extending outwardly.

Workout pants 130 can be comprised of any suitable material used for workout apparel as well known to those skilled in the art. The compressible hemispheres A can be disposed on workout pants 130 so as to be over or near the joints or other desired contact points of person P when workout pants 130 are worn. The compressible hemispheres A can contact the fitness equipment or other surface such as the floor during the workout. By configuring workout pants 130 in this manner, instability can be created when performing the workout which can allow additional muscles to be used and reduce strain on the joints of person P. Exercises such as “planking” or other floor exercises such as push-ups can be enhanced by having a compressible hemisphere placed between an elbow or knee or other contact point and the floor.

Also shown in FIG. 17, workout shirt 120 can be comprised of any suitable material used for workout apparel as well known to those skilled in the art. The compressible hemispheres A can be disposed on workout shirt 120 so as to be over or near the joints or other desired contact points of person P when workout shirt 120 is worn. The compressible hemispheres A can contact the fitness equipment or other surface such as the floor during the workout. By configuring workout shirt 120 in this manner, instability can be created when performing the workout which can cause the wearer to hold the body in proper alignment and allow additional muscles to be used and reduce strain on the joints of person P. In some embodiments, as shown in FIG. 17, workout shirt 120 can comprise hood portion 140. Hood portion 140 can be fitted to the head of person P and compressible hemispheres A can be disposed on head portion 142 or neck portion 144 of hood portion 140. In some embodiments, the workout garment can be a sleeve covering an arm of person P. The sleeve can comprise one or more compressible hemispheres A disposed thereon, extending outwardly.

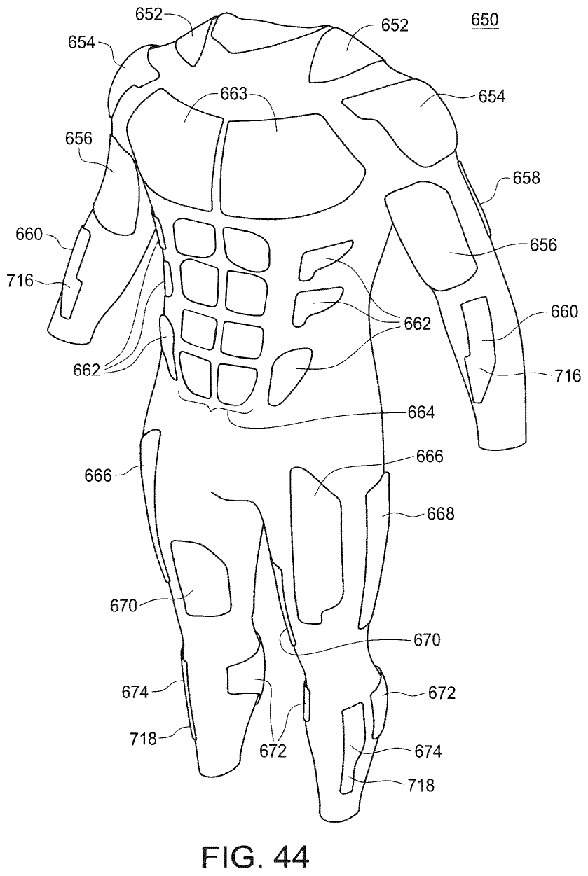

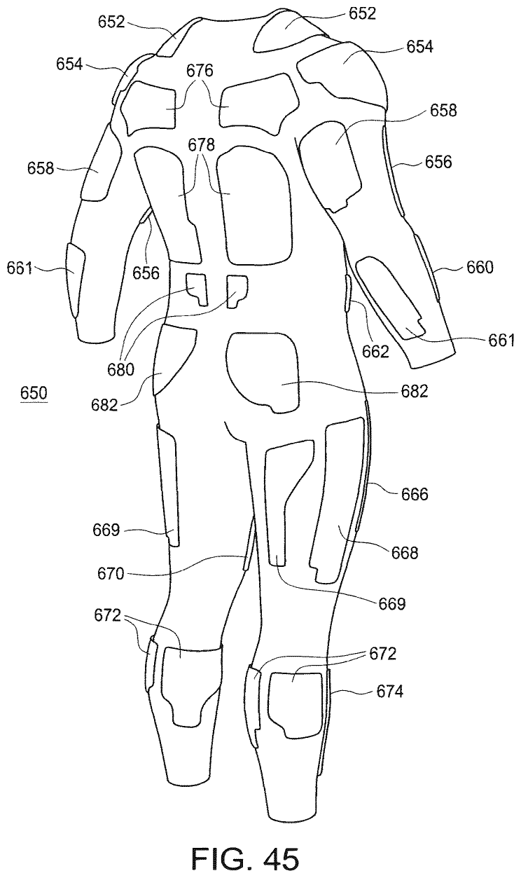

Referring to FIGS. 44 and 45, one embodiment of full-body workout suit 650 is shown. In some embodiments, workout suit 650 can comprise one or more of the following compressible members disposed thereon: neck compressible member 652, shoulder compressible member 654, bicep compressible member, 656 tricep compressible member 658, front forearm compressible member 660, rear forearm compressible member 661, side abdominal compressible member 662, pectoral compressible member 663, front abdominal compressible member 664, quadricep compressible member 666, outer thigh compressible member 668, hamstring compressible member 669, inner thigh compressible member 670, rear calf compressible member 672, front calf compressible member 674, upper back compressible member 676, mid-back compressible member 678, lower back compressible member 680 and gluteus compressible member 682. In some embodiments, workout suit 650 is intended to be tightly fitted on a person for when they are working out, so that a compressible member is situated as close as possible to a muscle group. Thus, when a person who is wearing workout suit 650 performs a movement, such as lifting a weight or moving a limb or body part, the muscle being worked will push out against workout suit 650 and press against the compressible member nearest to the muscle group being activated. In so doing, the contact between the muscle group and the compressible member can stimulate the nerves of the muscle group and trigger a proprioceptive effect during the movement. In some embodiments, workout suit 650 can comprise weights disposed on the forearms or calves of the suit that can intensify the effect of movement and of resistance training while wearing the suit. In some embodiments, workout suit 650 can comprise forearm weights 716 and calf weights 718, which can result in a person using a lighter weight or lower resistance setting on an exercise machine, so as to work the body in a natural and functional way.

In some embodiments, compressible hemispheres A can be integral with the workout garments. In some embodiments compressible hemispheres A can be removably attached to the workout garment. The workout garments can comprise pockets positioned at the desired location, as described above, for receiving the compressible hemisphere A. Other means of removable attachment of compressible hemispheres A can include Velcro™, hooks, buttons, snaps, straps or other suitable removable attachment as well known to those skilled in the art. In some embodiments compressible hemispheres can be interchanged for compressible hemispheres of different sizes or with different compressibility properties.

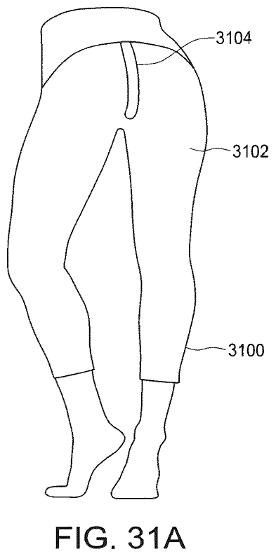

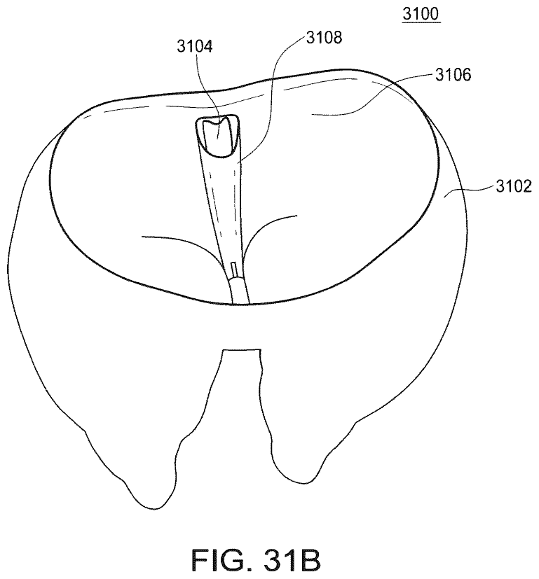

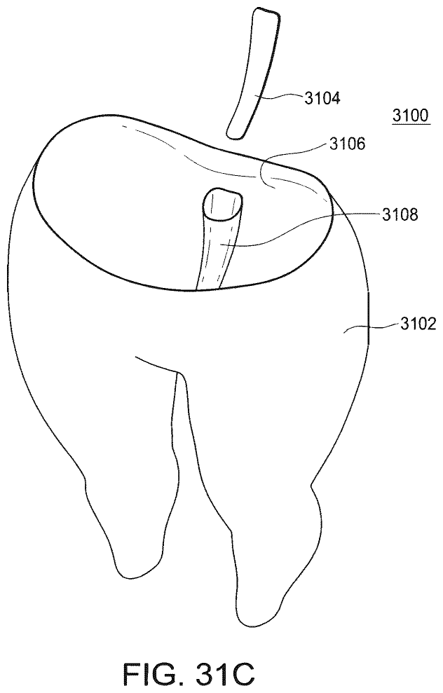

FIGS. 31a, 31b and 31c depicts a further embodiment of workout pants 3100. Workout pants 3100 can comprise one or more compressible member 3104 disposed therein. Workout pants 3100 can comprise exterior surface 3102 and interior surface 3106. In some embodiments, compressible member 3104 can be affixed to interior surface 3106, and can be positioned just below the sacrum of the person wearing workout pants 3100, wherein compressible member 3104 can extend downward along the intergluteal cleft. In some embodiments, pocket 3108 can be disposed provided on interior surface 3106 of workout pants 3100, wherein pocket 3108 can be configured for receiving compressible member 3104. In so doing, compressible member 3104 can be removed from pocket 3108 when workout pants 3100 are being laundered.

By configuring workout pants 3100 in this manner, instability can be created when performing a workout where the buttocks of the person are in contact with fitness equipment or other surface. Exercises can be enhanced by causing the person wearing the workout pants 3100 with compressible member 3104 to activate and engage the gluteus maximus muscles. Exercising using workout pants 3100 can cause the person to actively hold the muscles, joints and body in a proper alignment providing proprioceptive feedback to the CNS.

Referring to FIG. 18, one embodiment of improved workout sock 300 is shown. In some embodiments, workout sock 300 can comprise one or more compressible hemispheres A disposed thereon, extending outwardly. The compressible hemispheres A can be disposed on workout sock 300 on foot bottom 310, toe portion 320, instep 330, heel portion 340 or leg portion 350. In some embodiments, the leg portion 350 can extend above the knee. The compressible hemispheres can be comprised of the elastomeric or other durable materials as described above. In providing a workout sock with compressible hemispheres disposed on foot bottom 310, a person standing while wearing workout sock 300 can experience a similar effect to standing on an exercise dome and, thus, will need to hold the body in proper alignment and exert the use of additional muscles to maintain balance and stability. In providing a workout sock with compressible hemispheres disposed on other portions of workout sock 300, instability can be created at the contact point with the floor or exercise equipment when performing the workout which can allow additional muscles to be used and reduce strain on the joints of person. Compressible hemispheres A can be removably attached to workout sock 300 in the same manner described above with respect to the workout garments.

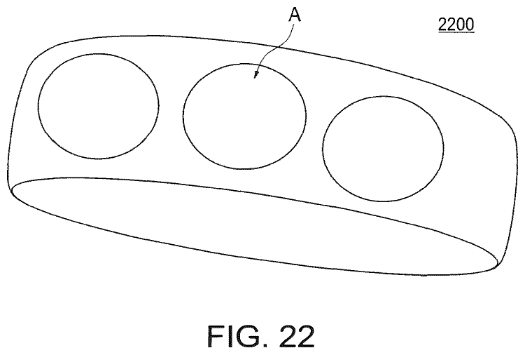

Referring to FIGS. 22, one embodiment of improved headband 2200 is shown. In some embodiments, headband 2200 can comprise one or more compressible hemispheres A disposed thereon, extending outwardly. The compressible hemispheres can be comprised of the elastomeric or other durable materials as described above. In providing a headband 2200 with compressible hemispheres disposed thereon, a person wearing headband 2200 can position headband 2200 such that instability can be created at the contact point with a surface or exercise equipment when performing the workout which can cause the wearer to hold the body in proper alignment and allow additional muscles to be used and reduce strain on the joints of person. Compressible hemispheres A can be removably attached to headband 2200 in the same manner described above with respect to the workout garments.

In some embodiments, the embodiments described above can comprise one or more pressure sensors 2580, which can measure the pressure applied to each of the protrusions. The pressure sensors 2580 can be positioned so as to be under the compressible protrusion or embedded within the compressible protrusions. In some embodiments, pressure sensors 2580 can comprise one of more of the following load sensing technologies: piezoresistive sensors, piezoelectric sensors, strain gauge sensors comprise wheatstone bridges, capacitive sensors, electromagnetic sensors, optical sensors, resistive sensors and any other load sensing technology as well known by those skilled in the art including, but not limited to, pressure sensitive fabric (see http://eeonyx.com/product_category/pressure-sensors/).

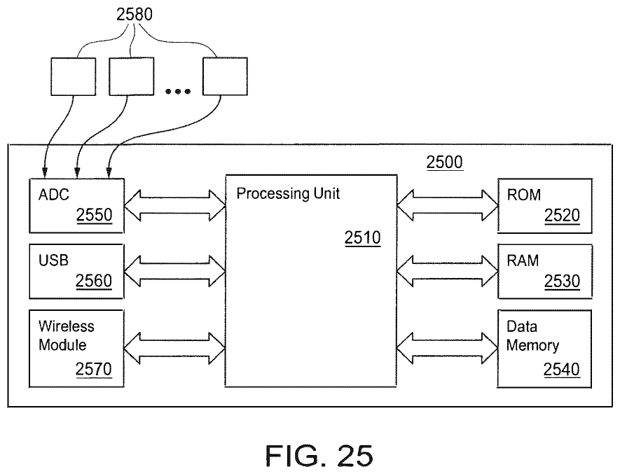

The embodiments described above can also comprise a microcontroller 2600. As shown in FIG. 25, the microcontroller can comprise processing unit 2510, one or more memory modules such as Read Only Memory (ROM) 2520, Random Access Memory (RAM) 2530, memory module 2540, analog to digital converter (ADC) 2550, and one or more communication module such as universal serial bus (USB) module 2560, wireless communication module 2570. Wireless communication module 2570 can comprise any suitable wireless communication protocol such as Bluetooth™, ZigBee™, Wi-FI™, or other wireless communication protocol as known to one skilled in the art.

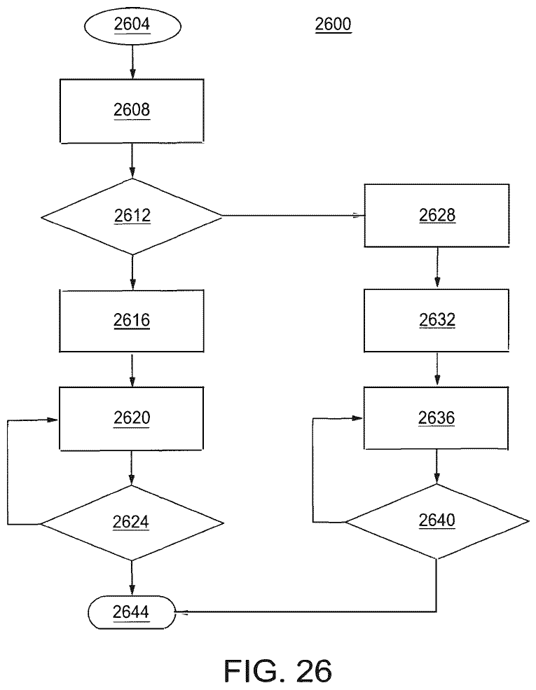

FIG. 26 depicts a flowchart showing an embodiment of the method 2600 for acquiring data from the pressure sensors 2580. Step 2604 can start the method 2600 when microcontroller 2500 is powered on. Step 2608 can initialize the ADC 2650 with parameters required to acquire the data from the pressure sensors 2580. Step 2608 can also initialize the USB 2560 and wireless 2570 communication modules. Step 2612 can determine if a device has been connected to the microcontroller 2500. This can be either to the USB module 2560 or wirelessly to the wireless communication module 2670. If a device is connected, the method 2600 can proceed to step 2616 where the microcontroller 2500 waits to receive a start data transmission signal. If no device is connected, the method 2500 can proceed to step 2628 and operate in an offline mode where pressure sensor data is stored to memory module 2540. Alternatively, step 2612 can be programmed to wait for a device to be connected to the microprocessor 2500 before proceeding to step 2616.

As mentioned, step 2616 can wait to receive a start transmission request from the connected device. The request can include a request to receive data from all or a subset of pressure sensors 2580. Step 2620 can transmit the requested sensor data to the connected device. Step 2624 can determine whether to stop the data transmission. Step 2624 can determine to stop transmission if a stop transmission request is received from the connected device, or alternatively, the transmission can be stopped if the connected device is disconnected. If step 2624 determines to stop transmission, the method can end at step 2644. In some embodiments, if step 2624 receives a stop transmission request from the connected device, the method 2600 can return to step 2616 to wait for a new start transmission request.

If no device is connected, step 2628 can initialize memory module 2540 to store the pressure sensor data. Step 2632 can wait to receive a start data capture request. The start data capture request can be a user input such as a button or switch. The start data capture request can also be determined by a threshold level on the pressure sensors 2580 where the data capture is initiated once a specified level of pressure is applied to any of the pressure sensors 2580. Step 2636 can store the sensor data to the memory module 2540. Step 2640 can determine whether to stop the data capture. Step 2640 can determine to stop capture if a stop capture request is received from the user. If step 2640 determines to stop the data capture, the method can end at step 2644. In some embodiments, if step 2640 receives a stop capture request, the method 2600 can return to step 2632 to wait for a new start capture request.

In some embodiments, as described below, compressible material can be positioned so as to be between the toes. The compressible material between the toes can activate the nerves in the toes and provide proprioceptive feedback to the CNS.

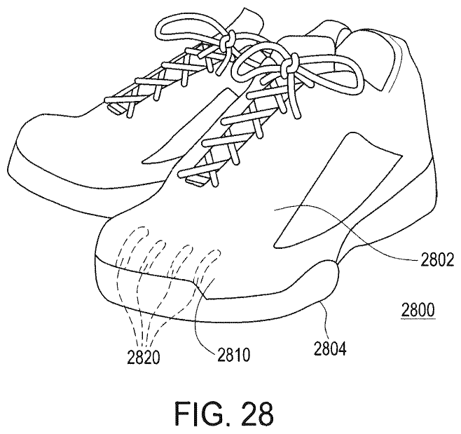

Referring to FIG. 28, an embodiment of a shoe is shown. Shoe 2800 can comprise sole portion 2804 and upper portion 2802. The sole 2804 and the upper 2802 can each comprise an inner surface which defines a foot cavity for receiving the foot of the user. The sole 2804 can comprise a toe region 2810 and one or more inter-toe compressible members 2820 which can be coupled to and extend upwards from the inner surface of toe region 2810 of sole 2804 to the inner surface of the upper 2802. The one or more inter-toe compressible members 2820 can be configured to fit between the toes of the user when the user's foot is placed inside the shoe 2800.

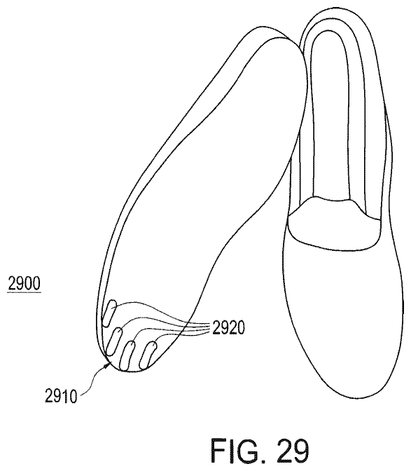

Referring to FIG. 29, an embodiment of a shoe insole is shown. In some embodiments, insole 2900 is configured to fit inside a shoe and can comprise toe region 2910 and one or more inter-toe compressible members 2920 which can be coupled to and extend upwards from the upper surface of toe region 2910 of insole 2900. The one or more inter-toe compressible members 2820 can be configured to fit between the toes of the user when the user's foot is placed inside a shoe containing the insole 2900.

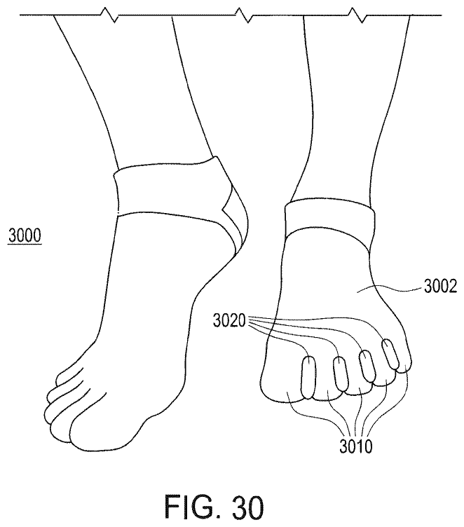

Referring to FIG. 30, an embodiment of an exercise sock is shown. Sock 3000 can be configured to cover portions of the sole or bottom region and portions of the instep or top of the foot. In this embodiment, the sock 3000 can comprise instep region 3002 adapted to cover the top or instep of a user's foot. Two or more toe regions 3010, configured to receive a toe of a foot can be coupled to or integral with the instep region 3002. In some embodiments, the two or more toe regions 3010 can comprise up to five toe regions 3010, one for each toe of the user's foot.

In some embodiments, sock 3000 can comprise one or more inter-toe compressible members 3020 between adjacent toe regions 3010. The inter-toe compressible members 3020 can be coupled to each of the adjacent toe regions 3010.

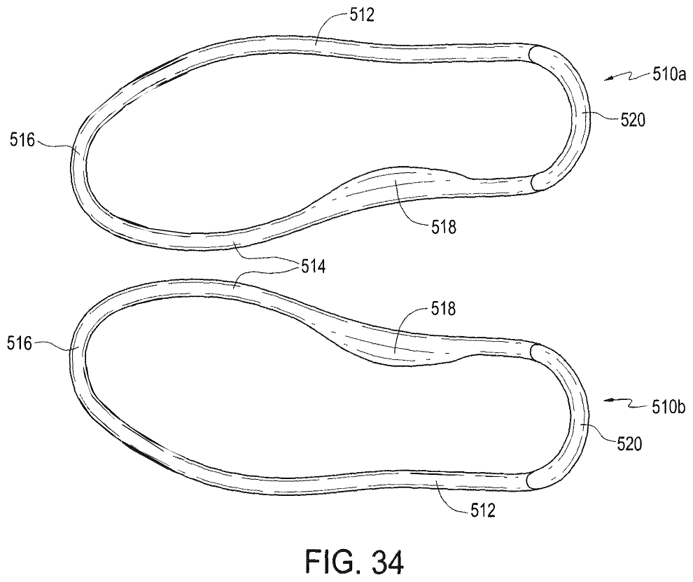

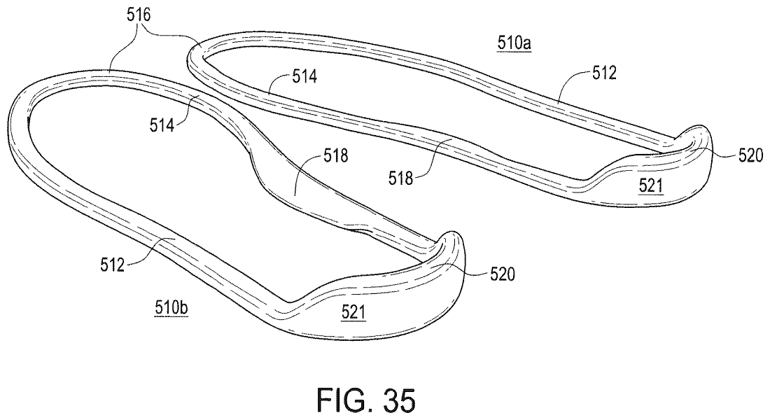

Referring to FIGS. 34 and 35, one embodiment of a shoe insert is shown. In some embodiments, the shoe inserts can comprise right shoe insert 510a and left shoe insert 510b, which can be mirror images of each other in configuration. In some embodiments, shoe inserts 510a and 510b can comprise a loop of a compressible material that can be configured in the shape of a shoe insole so that it can be inserted into and disposed around the interior perimeter within a cavity of a shoe, either in place of a conventional insole or in combination with a conventional insole. The compressible material can comprise the elastomeric material described above for the compressible protrusions. In some embodiments, shoe inserts 510a and 510b can comprise toe perimeter portion 516, outer perimeter portion 512, heel portion 520 and inner perimeter portion 514, all connected together, as shown in FIGS. 34 and 35, to provide proprioceptive support around the perimeter of a person's foot when wearing the shoe. In some embodiments, inner perimeter portion 514 can further comprise arch support 518 to provide support to the arch of a person's foot when insert 510a or 510b is placed within a shoe. In some embodiments, heel portion 520 can further comprise an elevated or raised heel support 521 disposed thereof for providing further support to the heel of a person wearing a shoe with insert 510a or 510b placed therein.

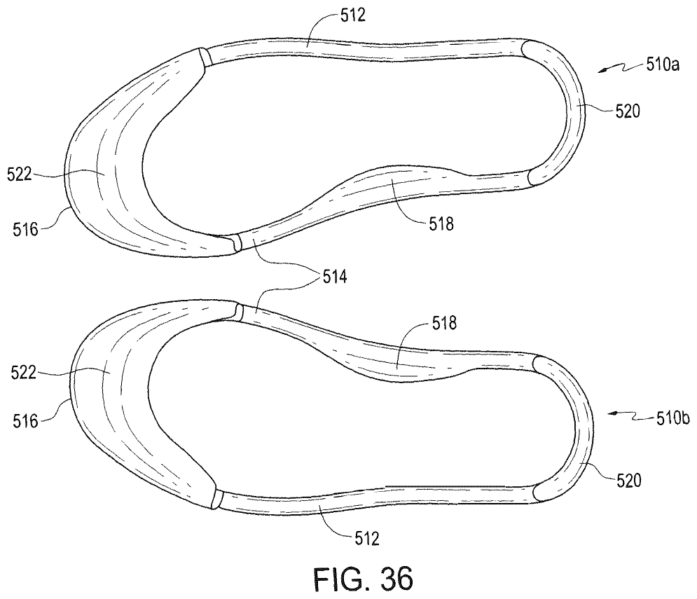

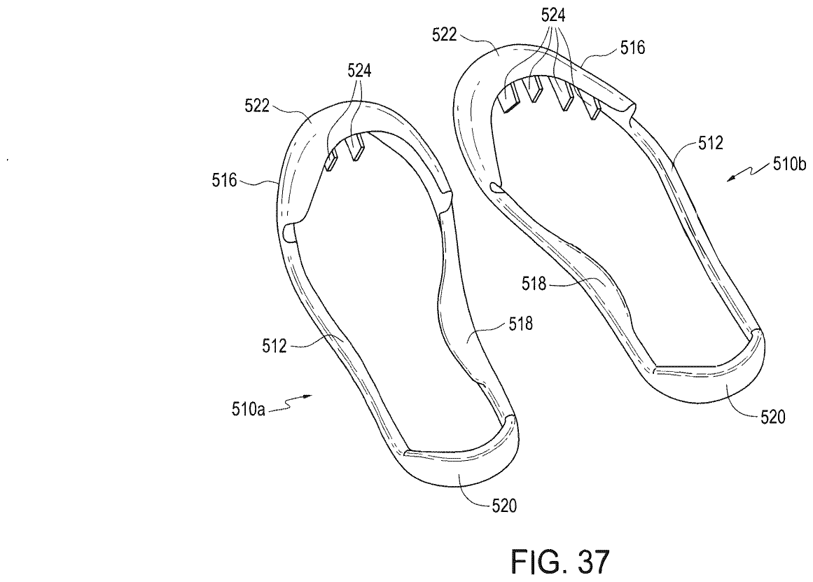

Referring to FIGS. 36 and 37, another embodiment of shoe inserts 510a and 510b is shown. In this embodiment, the shoe inserts can further toe cap 522 disposed on toe perimeter portion 516 that can cover at least a portion of a person's toes when the shoe is worn. In some embodiments, toe cap 522 can further comprise one or more toe dividers 524 extending downwardly therefrom, as shown in FIG. 37, to separate the toes and to provide proprioceptive support therebetween.

In some embodiments, toe dividers 524 can comprise compressible material positioned between the toes. The compressible material between the toes can activate the nerves in the toes and provide proprioceptive feedback to the CNS.

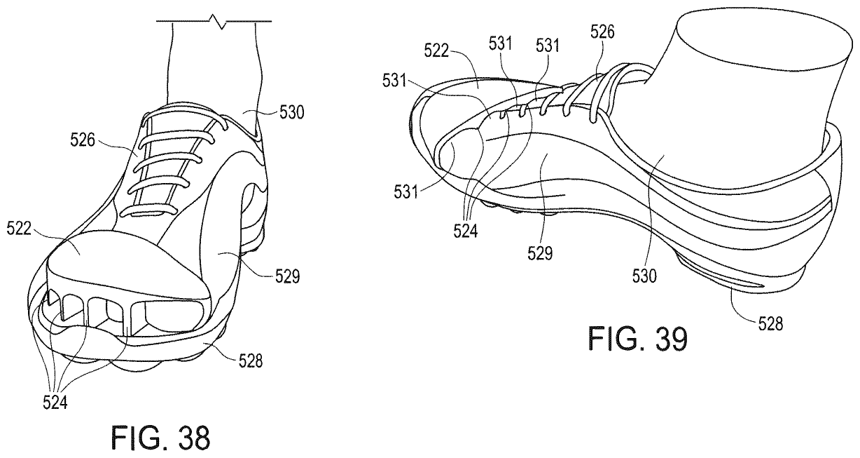

Referring to FIGS. 38 and 39, an embodiment of shoe 526 comprising top cap 522 is shown. Shoe 526 can comprise sole portion 528 and upper portion 529. Sole 528 and upper portion 529 can each comprise an inner surface which defines a foot cavity for receiving the foot of the user. Sole 528 can comprise one or more compressible toe dividers 524 that can be coupled to and extend downwards from an inner surface of toe cap 522. One or more toe dividers 524 can be configured to fit between the toes of the user when the user's foot is placed inside shoe 526.

In some embodiments, shoes can be provided that comprise at least one compressible protrusion extending downwardly from the soles. In configuring shoes in this manner, instability can be created when the protrusion is located between the users foot and a surface such as when standing when lifting weights, using weight/resistance equipment, performing floor exercises or other stretching activities, which can allow additional muscles to be used during a weight lifting exercise without comprising the joints of the person lifting the weight. This can also cause the user to actively hold the muscles, joints and body in a proper alignment providing proprioceptive feedback to the CNS. These voluntary movements can be repeated and stored as central commands. This patterning of the brain allows various skills to be performed without continuous without continuous reference to consciousness and can increase the conscious and unconscious awareness of the joint or limb in motion.

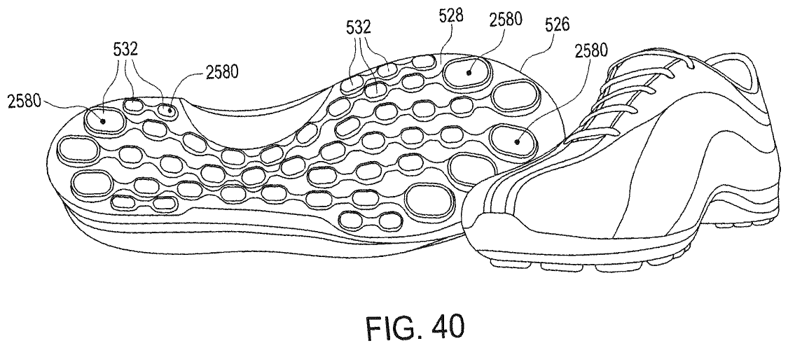

Referring to FIG. 40, one embodiment of shoe 526 is shown. In some embodiments, sole 528 of shoe 526 can comprise compressible protrusions 532 extending downwardly therefrom. For illustrative purposes only, only a few of protrusions 532 are labelled. In some embodiments, shoe 526 can comprise one or more pressure sensors 2580 disposed in one or more of protrusions 532, which can measure the pressure applied to each of the protrusions. In some embodiments, pressure sensors 2580 can be placed between the protrusions and the exterior surface of shoe 526, or can be embedded within protrusions 532, or both. In some embodiments, pressure sensors 2580 can comprise one of more of the following load sensing technologies: piezoresistive sensors, piezoelectric sensors, strain gauge sensors comprise wheatstone bridges, capacitive sensors, electromagnetic sensors, optical sensors, resistive sensors and any other load sensing technology as well known by those skilled in the art including, but not limited to, pressure sensitive fabric (see http:/eeonyx.com/product_category/pressure-sensors/). In some embodiments, a combination of shoe 526 with pressure sensors 2560 disposed in protrusions 532 can communicate with microcontroller 2500, operating method 2600, as described above and illustrated in FIGS. 25 and 26.

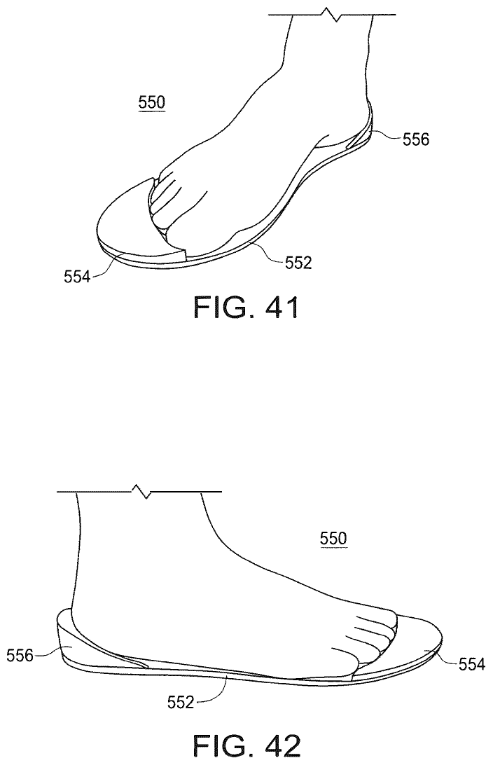

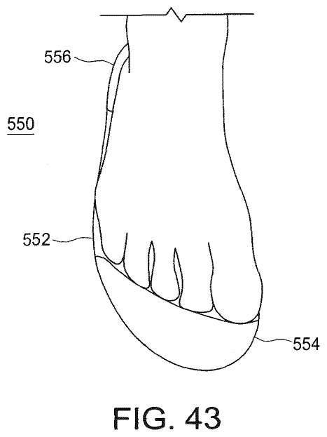

Referring to FIGS. 41 to 43, another embodiment of a shoe insert is shown. In some embodiments, shoe insert 550 can comprise sole 552 having toe compressible member 554 and heel compressible member 556 disposed thereon, as shown FIGS. 41 to 43. In this embodiment, shoe insert 550 can be configured to be inserted into a shoe as an insole, or be comprised in a shoe as it is made. A person's toes can press against toe compressible member 554, and their heel can rest within or on heel compressible member 556, wherein contact with the compressible members can stimulate the person's nerves in their foot to trigger a proprioceptive effect when the person walks, runs or performs physical movements when wearing a shoe with the compressible members disposed therein.

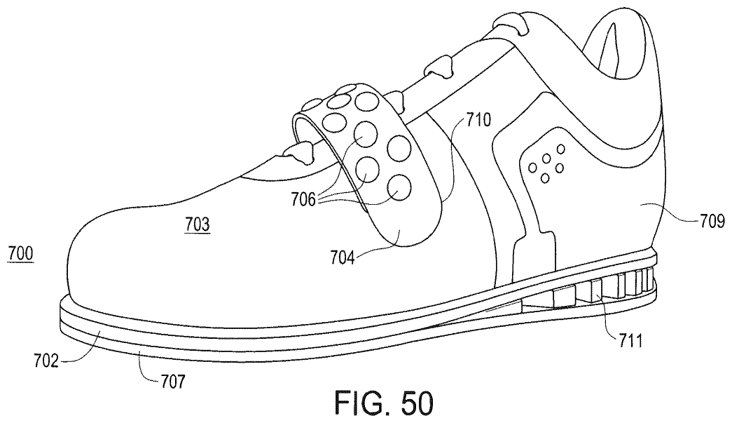

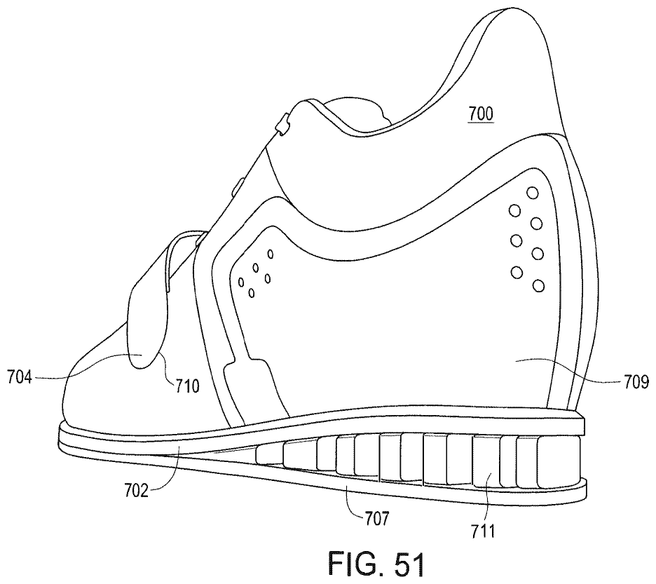

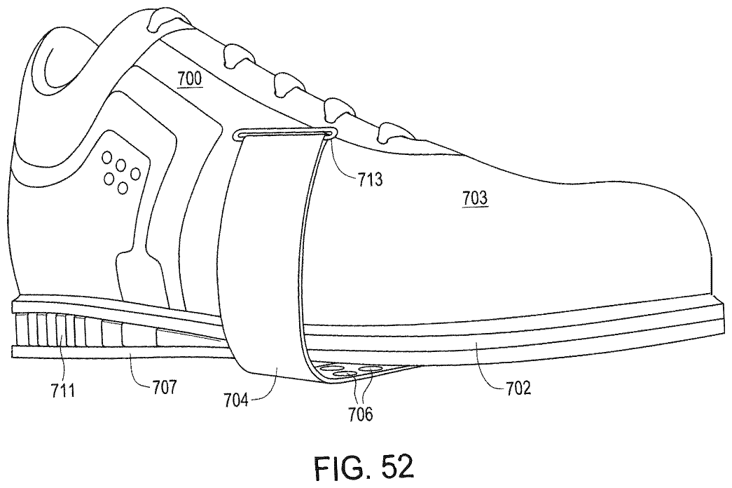

Referring to FIGS. 50 to 52, one embodiment of a convertible cross-training shoe is shown. In some embodiments, cross-training shoe 700 can comprise strap 704 that can comprise one end thereof affixed to upper 703 via ring coupler 713, with the other end of strap 704 configured to attach at location 710 on shoe upper 703, using a hook and loop fastener, as an example, or with any other fastening means as well known to those skilled in the art including, without limitation, snaps, buttons, buckles and the like. In some embodiments, strap 704 can comprise a plurality of compressible members 706 disposed thereon. In some embodiments, strap 704 can be positioned over shoe upper 703, as shown in FIGS. 50 and 51, such that strap 704 is in contact with shoe upper 703. In this configuration, compressible members 706 can provide a proprioceptive effect to the top of a person's foot when they are walking while wearing shoe 700 with compressible members 706 compressed against shoe upper 703. In some embodiments, strap 704 can be wrapped around sole 702 and tread 707, as shown in FIG. 52, such that strap is in contact with tread 707. In this configuration, compressible members 706 can provide a proprioceptive effect to the sole of a person's foot when they are exercising or in a training session. When the person has completed their training session, strap 704 can then be returned to its position on shoe upper 703, as shown in FIGS. 50 and 51. In some embodiments, shoe 700 can comprise compressible member 711 that can be placed on heel 709 of the shoes, and disposed between sole 702 and tread 707, to provide a cushioning effect on the heel of a person when walking or exercising.

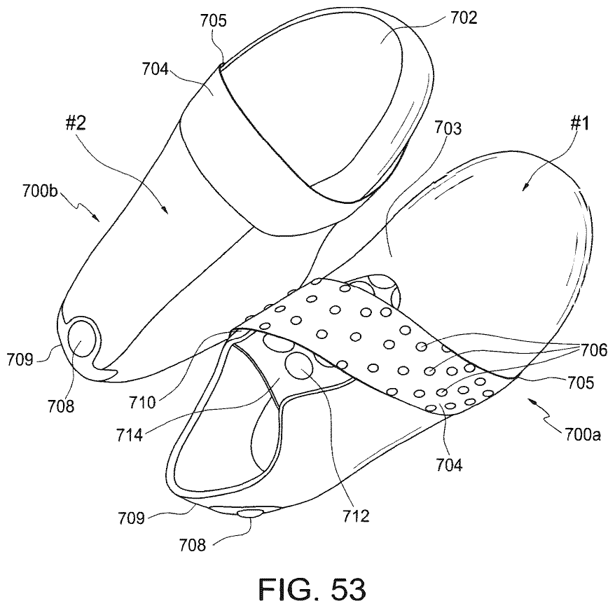

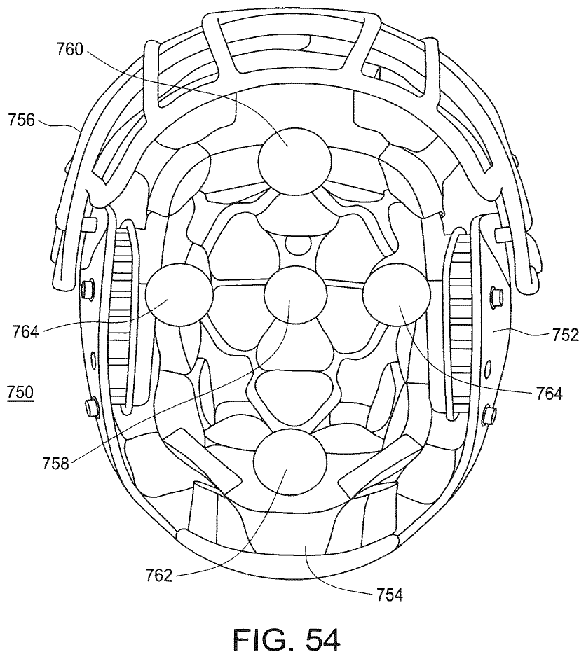

Referring to FIG. 53, an alternate embodiment of a convertible cross-training shoe is shown. In some embodiments, cross-training shoes 700a and 700b can comprise strap 704 that can comprise one end thereof affixed at location 705 on sole 702, with the other end of strap 704 configured to attach at location 710 on shoe upper 703, using a hook and loop fastener, as an example, or with any other fastening means as well known to those skilled in the art including, without limitation, snaps, buttons, buckles and the like. In some embodiments, strap 704 can comprise a plurality of compressible members 706 disposed thereon. In some embodiments, strap 704 can be positioned over shoe upper 703, as shown on shoe 700a, such that strap 704 is in contact with shoe upper 703. In this configuration, compressible members 706 can provide a proprioceptive effect to the top of a person's foot when they are walking while wearing shoe 700a with compressible members 706 compressed against shoe upper 703. In some embodiments, strap 704 can be wrapped around sole 702, as on shown on shoe 700b, such that strap is in contact with sole 702. In this configuration, compressible members 706 can provide a proprioceptive effect to the sole of a person's foot when they are exercising or in a training session. When the person has completed their training session, strap 704 can then be returned to its position on shoe upper 703, as shown on shoe 700a. In some embodiments, shoes 700a and 700b can comprise compressible member 708 that can be placed on heel 709 of the shoes. In some embodiments, compressible member 708 can attach to heel 709 with a hook and loop fastener or with any other fastening means as described above. In some embodiments, compressible member 708 can be attached to sole 702 such that compressible member 708 can flip between a first position on sole 702 when training (as shown on shoe 700b) to a second position on the back of heel 709 when walking (as shown on shoe 700a). In some embodiments, shoes 700a and 700b can comprise one or more weights 712 disposed thereon. As shown on shoe 700a, weights 712 can be disposed on tongue 714, although weights 712 can be positioned at any suitable position on shoe upper 703 or disposed within sole 702. By providing weights 712 within shoes 700a and 700b, the weights, even in small amounts, can intensify the effect of movement while walking or running while working the body in a natural and functional way. In exercise involving the use of free weights, providing additional weights 712 in the shoes can reduce the amount of free weight used by the person performing the exercise allowing the person to move more freely without restriction, which can be more athletic in nature.

Referring to FIG. 51, a sports helmet is shown having compressible members disposed therein that can provide further stabilization of an athlete's head when wearing such a helmet. In some embodiments, helmet 750 comprising outer shell 752 and inner liner 754 can comprise one or more compressible members disposed on liner 754. In the illustrated embodiment, helmet 750 is presented as a football helmet having facemask 756, although the embodiments described herein can equally apply to hockey helmets, ski helmets, bicycle helmets, skateboard helmet, motorsport helmet or any other form of helmet for sporting activities, whether comprising a facemask or not. In some embodiments, liner 754 can comprise forehead compressible member 760 for contacting the forehead of the athlete, top compressible member 758 for contacting the top of the head of the athlete, rear compressible member 762 for contacting the back of the head of the athlete, and side compressible members 764 for contacting the left and right sides of the head of the athlete. By providing compressible members in helmet 750 in this manner, the athlete's head can have constant direct contact with the compressible members, which can assist in stabilizing and protecting the athlete's head in helmet 750 when contacted by another athlete or struck when colliding with the ground, or any other surface of the environment of the sporting activity that the athlete is participating in.

Although a few embodiments have been shown and described, it will be appreciated by those skilled in the art that various changes and modifications can be made to these embodiments without changing or departing from their scope, intent or functionality. The terms and expressions used in the preceding specification have been used herein as terms of description and not of limitation, and there is no intention in the use of such terms and expressions of excluding equivalents of the features shown and described or portions thereof, it being recognized that the invention is defined and limited only by the claims that follow.

1. A method for inducing a person to use additional muscles and to hold the additional muscles, their joints and their body in a proper alignment providing proprioceptive feedback to their central nervous system (“CNS”) when gripping a barbell, a dumbbell or other like weight or resistance equipment during physical exercise, the method comprising:
a) the person wearing a glove on a hand, the glove comprising at least one compressible protrusion disposed on the glove extending outwardly from an exterior surface thereof, wherein the at least one compressible protrusion extends away from the hand when the hand is placed in the glove, wherein the exterior surface further comprises a plurality of phalange regions comprising the at least one compressible protrusion extending outwardly therefrom, wherein the at least one compressible protrusion extends away from the hand when the hand is placed in the glove, wherein each of the plurality of phalange regions comprises a dorsal phalange region and wherein the at least one compressible protrusion comprises a first dorsal compressible protrusion and a second dorsal compressible protrusion each extending outwardly from at least one of the dorsal phalange regions of the plurality of phalange regions, wherein the at least one compressible protrusion extends away from the hand when the hand is placed in the glove; and
b) creating instability during the gripping of the barbell or the dumbbell with the at least one compressible protrusion being compressed as the person is gripping the barbell or the dumbbell with the hand during the physical exercise thereby causing the person to use the additional muscles and to hold the additional muscles, the joints and the body in the proper alignment providing the proprioceptive feedback to the CNS.

2. The method as set forth in claim 1, wherein the exterior surface further comprises an anterior region comprising the at least one compressible protrusion extending outwardly therefrom, wherein the at least one compressible protrusion extends away from the hand when the hand is placed in the glove.

3. The method as set forth in claim 1, wherein the exterior surface further comprises a dorsal region comprising the at least one compressible protrusion extending outwardly therefrom, wherein the at least one compressible protrusion extends away from the hand when the hand is placed in the glove.

4. The method as set forth in claim 1, wherein each of the plurality of phalange regions further comprises a fingertip region comprising the at least one compressible protrusion extending outwardly therefrom, wherein the at least one compressible protrusion extends away from the hand when the hand is placed in the glove.

5. The method as set forth in claim 1, wherein each of the plurality of phalange regions comprises an anterior phalange region and wherein the at least one compressible protrusion comprises a first anterior compressible protrusion and a second anterior compressible protrusion each extending outwardly from at least one of the anterior phalange regions of the plurality of phalange regions, wherein the at least one compressible protrusion extends away from the hand when the hand is placed in the glove.

6. The method as set forth in claim 5, wherein the first anterior compressible protrusion and the second anterior compressible protrusion are connected by an anterior connecting material.

7. The method as set forth in claim 1, wherein the first dorsal compressible protrusion and the second dorsal compressible protrusion are connected by a dorsal connecting material.

8. The method as set forth in claim 1, wherein the at least one compressible protrusion comprises one or more of a group comprising rubber, thermoplastic rubber, foam rubber, polyurethane rubber, silicone rubber, thermoplastic resin and thermoplastic elastomer.

9. The method as set forth in claim 1, further comprising measuring pressure during the physical exercise with at least one pressure sensor disposed within the at least one compressible protrusion or between the glove and the at least one compressible protrusion.

10. The method as set forth in claim 9, wherein the glove further comprises a microcontroller, the microcontroller comprising:
a) a processor;
b) at least one memory module;
c) at least one communication module;
d) an analog to digital converter; and
e) a power supply,
wherein the at least one pressure sensor is operatively coupled to the analog to digital converter.

11. The method as set forth in claim 1, wherein the glove further comprises weights disposed on one or both of a dorsal region of the glove and a backside of one or more digits of the glove.
